(19) United States
(12) Patent Application Publication
(10) Pub. No.: US 2026/0236651 A1
(43) Pub. Date: Aug. 13, 2026

(54) A PIPELINED RESOURCE SHARING SYSTEM FOR DATAFLOW HIGH-LEVEL SYNTHESIS

(71) Applicant: Yale University, New Haven, CT (US)

(72) Inventors: Rui Li, New Haven, CT (US); Rajit Manohar, New Haven, CT (US)

(21) Appl. No.: 18/436,991

(22) Filed: Feb. 8, 2024

Related U.S. Application Data
(60) Provisional application No. 63/484,363, filed on Feb. 10, 2023.

(51) Int. Cl. G06F 30/327

(52) U.S. Cl. CPC G06F 30/327

(57) ABSTRACT

Provided herein are methods of forming a fully-pipelined dataflow circuit. The methods include mapping a program into the dataflow circuit through dataflow high-level synthesis (HLS), the dataflow HLS including a compilation stage comprising synthesizing functions into separate hardware modules and a linking stage comprising generating logic to combine the hardware modules into a whole program dataflow graph; and generating the dataflow circuit; wherein at least one link in the dataflow circuit is slack elastic.

### CROSS-REFERENCE TO RELATED APPLICATIONS

The present application claims priority under 35 U.S.C. § 119 (e) to U.S. Provisional Patent Application No. 63/484,363, filed Feb. 10, 2023, which application is incorporated herein by reference in its entirety.

### STATEMENT REGARDING FEDERALLY SPONSORED RESEARCH OR DEVELOPMENT

This invention was made with government support under FA8650-18-2-7850 awarded by Air Force Research Laboratory (AFRL) and HR0011-15-1-7580 awarded by DARPA. The government has certain rights in the invention.

### BACKGROUND OF THE INVENTION

Historically, transistor technology scaling provided significant improvements in performance, power, and integration density every few years. This trend has slowed down significantly in today's sub-10 nm regime To continue satisfying the insatiable needs for high-performance and energy-efficiency, computer system designers have been forced to move from general-purpose microprocessors to field-programmable gate arrays (FPGAs) and both domain-specific and problem-specific accelerators.

Designing a system that contains a large collection of accelerators in addition to high-performance CPUs is a non-trivial task. An appealing approach to reducing design complexity is to adopt a design flow using high-level synthesis (HLS). HLS is the compilation process which maps high-level algorithms, typically expressed in C and C++, into hardware description language specifying a digital circuit. The synthesis is divided into two steps: i) parse the software program and generate the Control-Data Flow Graph (CDFG), which captures the control/data dependencies of the original program; and ii) map the CDFG into either statically scheduled circuit (using statically scheduled HLS) or dataflow circuit (using dataflow HLS).

CDFG. First of all, the HLS frontend will generate a control flow graph (CFG), which is the standard data structure used for optimizing software programs. Nodes in this graph are basic blocks, which correspond to a collection of consecutive sequential statements. Outgoing edges from a basic block correspond to different potential successors, with the successor chosen based on a specified condition. For-loops and while-loops result in cycles in the CFG. Then, for each basic block, a data flow graph (DFG) is generated to capture the data dependencies among instructions within it. A CDFG is the combination of CFG and DFGs for all of the basic blocks.

### Static HLS

The static HLS converts a program into the statically scheduled circuit, which consists of a datapath that contains all the operations (e.g., addition, multiplication, etc.) from the program and a finite state machine that schedules these operations into clock cycles. The state machine serves as a global scheduler that controls the execution sequence of the whole circuit. Statically scheduled HLS faces several challenges which could largely affect the quality of the generated circuits. For one, the tool requires accurate delay information of each operator before synthesis, which is coupled with specific technology nodes used to implement the circuit, and is not always available. Additionally, when the source program has conditional (e.g., switch, if and nested if) statements, the HLS will trigger the execution of all of the branches regardless of the conditions. This will increase the energy consumption of the circuit and, to make things worse, the circuit has to wait for the slowest branch to finish regardless of the conditions. Furthermore, the tool schedules all operators into different clock cycles (i.e., different pipeline stages), and it is essential that these pipelines have balanced delays. Since the clock signal is shared across the whole pipelines, the HLS engine needs to carefully schedule the operators so that each stage does not waste too much time waiting. Still further, the tool needs to decide the degree of pipelining before actual execution. Several tools use the directives inserted into the original source program to make better decisions. However, this relies on the hardware expertise from software programmers and the circuit's runtime information, both are challenging in practice. Moreover, the whole circuit needs to be re-synthesized on partial circuit changes, because the static HLS needs to synthesize a state machine that captures the behaviors of all elements in the whole circuit.

### Dataflow HLS

The dataflow HLS converts a program into the dataflow circuit which uses concurrent, parallel dataflow components as hardware building blocks. Unlike the static HLS, it results in distributed control and an implicit pipelined implementation. More specifically, an application is represented as a directed graph, known as a dataflow graph (DFG), of computational blocks with edges defining communication channels between them. The data transferred between blocks is called tokens. When a computation block receives all of the required input tokens from its predecessors, it will operate on the inputs, generate the output and send it to its successor(s). A block remains idle if it does not receive all of the required input data. Dataflow circuits can be automatically pipelined because they get rid of the global control; ironically, they are hard to be fully pipelined due to the lack of such global control for accessing the shared resources.

Accordingly, there is a need in the art for articles and methods that improve on existing articles, programs and methods for increasing performance and energy-efficiency by high-level synthesis of dataflow circuits. The present invention addresses this need.

### SUMMARY OF THE INVENTION

In one aspect, a method of forming a fully-pipelined dataflow circuit includes mapping a program into the dataflow circuit through dataflow high-level synthesis (HLS) and generating the dataflow circuit, wherein at least one link in the dataflow circuit is slack elastic. In some embodiments, the dataflow HLS includes a compilation stage comprising synthesizing functions into separate hardware modules and a linking stage comprising generating logic to combine the hardware modules into a whole program dataflow graph.

In some embodiments, the synthesizing of the functions into the separate hardware modules includes mapping of each function that does not involve function calls into the separate hardware modules. In some embodiments, the functions are mapped into independent circuits. In some embodiments, the independent circuits are independent asynchronous dataflow circuits. In some embodiments, the compilation stage includes synthesizing dangling dataflow connections across functions.

In some embodiments, the linking stage includes constructing a pipelined linking circuit, the pipelined linking circuit resolving the dangling dataflow connections. In some embodiments, constructing the pipelined linking circuit includes generating a pipelined resource sharing system. In some embodiments, constructing the pipelined linking circuit includes forming an adaptive control token network (ACTN). In some embodiments, forming the ACTN includes generating at least one use-resource token. In some embodiments, each use-resource token determines how many times a function is called at run-time by a program fragment. In some embodiments, a different use-resource token is generated for each different invocations of the program fragment.

In some embodiments, the program includes at least one sequential composition; the at least one sequential composition has at least two sub-programs composed in a sequential fashion; and each of the at least two sub-programs has at least one possible invocation of the same function. In some embodiments, the program including at least one sequential composition further includes introducing a MERGE block, the MERGE block routing an argument to the function; introducing a SPLIT block, the SPLIT block routing a return value from the function; computing the use-resource token for the sequential composition from the at least two sub-programs; and generating a control token, the control token routing data tokens through the MERGE and SPLIT blocks. In some embodiments, the method further includes inserting a first in, first out (FIFO) buffer at the SPLIT block.

In some embodiments, the program includes at least one conditional composition, the at least one conditional composition calling one or more of the functions in a conditional fashion. In some embodiments, the program including at least one conditional composition further includes introducing a MERGE block, the MERGE block routing a conditional argument to the function; introducing a SPLIT block, the SPLIT block routing a return value according to the conditional argument from the function; computing a conditional use-resource sequence for each conditional branch; computing the use-resource token for the conditional composition from the conditional use-resource sequences; and generating a control token, the control token routing data tokens through the MERGE and SPLIT blocks. In some embodiments, the method further includes inserting a first in, first out (FIFO) buffer at the SPLIT block.

In some embodiments, the program includes at least one iterative composition, the at least one iterative composition calling one or more loops of the function. In some embodiments, the method further includes computing the use-resource token for the iterative composition, the use-resource token being run-length encoded with the number of loops in the iterative composition.

In some embodiments, the method further includes introducing a proxy function for indirect function calls; and generating a use-resource token network including direct function call use-resource tokens and indirect function call use-resource tokens. In some embodiments, the method further includes generating incremental linking to route data from the proxy function to the function. In some embodiments, the method further includes generating one or more control tokens for the incremental linking.

In some embodiments, the method further includes treating both memory blocks and function blocks as shared resource blocks. In some embodiments, the method further includes generating one or more function pointer arguments.

In some embodiments, the method further includes clustering FUNC operators within a basic block into a monolithic FUNC operator.

In some embodiments, the method further includes MERGE and SPLIT flattening.

In some embodiments, the method further includes fusing at least one SPLIT and MERGE pair.

In some embodiments, the method further includes clustering FUNC modules across basic block boundaries.

### BRIEF DESCRIPTION OF THE DRAWINGS

FIG. 1 shows an image illustrating dataflow elements.

FIG. 2 shows an image illustrating a dataflow circuit example.

FIGS. 3A-D show images illustrating example code for function calls. (A) Two invocations to ƒ. (B) Sequential code. (C) Conditional code. (D) Loop code.

FIGS. 4A-D show images illustrating different resource sharing options. (A) Resource sharing problem. (B) Replication. (C) Blocking access. (D) Pipelined access.

FIGS. 5A-B show images illustrating side effects of the function invocation. (A) Modify memory. (B) Update static variable.

FIGS. 6A-C show images illustrating a distributed token network approach to handling shared function calls. (A) General structure of token-based mutual exclusion. (B) Example showing that a token must follow the control flow of the original program. (C) Problem 1.

FIG. 7 shows a rewrite of the loop code.

FIGS. 8A-B show a drawback of distributed token network. (A) Control flow graph. (B) Problem 2.

FIGS. 9A-C show images illustrating a token network template. (A) Sequential composition (SEQ). (B) IF_c. (C) LOOP_c.

FIG. 10 shows an image illustrating an example program with multiple function calls, and the corresponding extended call graph.

FIGS. 11A-B show images illustrating a Token Network example, showing the view of g as far as access to the function ƒ is concerned. (A) Code for g, simplified to remove the array A. (B) TN(g,f). Notice that the call to h has been replaced with the proxy hƒ ports and potential calls ƒ³ and ƒ⁴, since h may call ƒ.

FIGS. 12A-C show images illustrating incremental linker datapath. (A) Compilation+Token Network generation. (B) Linker datapath for data tokens. (C) Linker datapath for control tokens.

FIGS. 13A-B show images illustrating a linker design. (A) Linker control path generation. (B) Linker complete design.

FIG. 14 shows an image illustrating a pointer example.

FIG. 15 shows an image illustrating split and merge fusion.

FIG. 16 shows an image illustrating normalized per-benchmark performance in default setting: delay (D), area (A), energy (E), leakage power (L), and throughput-inv (1/T).

FIG. 17 shows an image illustrating normalized performance (compared to Legup). The dark color represents the default setting for each tool, and the corresponding light color represents the other case.

FIGS. 18A-C show program partition of a program including multiple functions which can call each other according to an embodiment of the disclosure. (A) Full program including two functions m and f. m calls f in the function body, while f is a sing-input-single-output function. (B) Compilation stage. (C) Linking stage.

FIGS. 19A-B show system overviews of a program according to an embodiment of the disclosure. (A) Compilation stage handles code without function calls, which is mapped into independent circuits with dangling ports. (B) Linking stage includes only function calls, and involves connecting the dangling ports generated in the compilation stage.

FIG. 20 shows images illustrating various dataflow elements.

FIGS. 21A-C show images illustrating an example for high-level synthesis (HLS). (A) Example code. (B) Scheduling. (C) Final circuit.

FIGS. 22A-C show images illustrating an iƒ example. (A) Example iƒ statement code. (B) Static token form (STF). (C) Final circuit.

FIGS. 23A-C show images illustrating a loop example. (A) Example loop statement code. (B) Static token form (STF). (C) Final circuit.

FIGS. 24A-B show schematics illustrating canonical forms of (A) if and (B) loop blocks.

FIGS. 25A-D show images illustrating if condition extraction. (A) Initial. (B) Step 1. (C) Step 2. (D) Step 3.

FIGS. 26A-C show images illustrating loop condition extraction. (A) Initial. (B) Step 1. (C) Step 2.

FIGS. 27A-C show images illustrating delivery and collection circuits. (A) Control-Data Flow Graph (CDFG). (B) Delivery circuit for (B₀, B₂). (C) Collection circuit for B₅.

FIGS. 28A-D show images illustrating control token generation. (A) c′₁ generation. (B) c′₂ generation. (C) New delivery circuit. (D) New collection circuit.

FIGS. 29A-C show images illustrating a multi-path example. (A) Control-Data Flow Graph (CDFG). (B) Strawman delivery circuit. (C) Dilemma in building the delivery circuit.

FIGS. 30A-B show images illustrating multi-path problem and solution. (A) Illustration. (B) Solution.

FIGS. 31A-E show images illustrating irregular loop and solution. (A) Multi-exit illustration. (B) Multi-exit solution. (C) Multi-enter illustration. (D) Multi-enter solution. (E) Flag generation.

FIG. 32 shows images of non-deterministic dataflow elements.

FIGS. 33A-D show images illustrating an operator clustering example. (A) Example code. (B) IR instructions. (C) Vanilla dataflow graph. (D) Improved dataflow graph.

FIGS. 34A-B show images of SPLIT tree flattening. (A) SPLIT tree. (B) 3-way SPLIT.

FIG. 35 shows a schematic of a bundled-data circuit template.

FIGS. 36A-C show graphs illustrating various performance breakdowns. (A) Delay comparison. (B) Area comparison. (C) LeakPower comparison.

FIGS. 37A-B show graphs illustrating various performance breakdowns. (A) Energy comparison. (B) Throughput comparison.

FIG. 38 shows graphs illustrating normalized performance for HLS benchmarks: delay (D), area (A), energy (E), leakage power (L), and throughput-inv (1/T).

FIG. 39 shows graphs illustrating normalized performance for micro bench.

### DETAILED DESCRIPTION OF THE INVENTION

### Definitions

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are described.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of +20% or +10%, more preferably +5%, even more preferably +1%, and still more preferably +0.1% from the specified value, as such variations are appropriate to perform the disclosed methods.

Ranges: throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

As used herein, the term “slack elastic” refers to a system or component of a system where an arbitrary amount of buffering can be added on any link and/or along any communication channel without affecting the correctness of the system.

As used herein, the term “fully-pipelined” refers to a system where pipelining can be added anywhere without re-synthesizing the system and without affecting the correctness of the system (i.e., without making the computation incorrect).

### DETAILED DESCRIPTION

Provided herein are methods of generating fully-pipelined dataflow circuits. In some embodiments, the method includes mapping a program into the dataflow circuit through high-level synthesis (HLS) and generating the dataflow circuit. The circuits include any suitable circuits, such as, but not limited to, synchronous or asynchronous circuits. The HLS includes any suitable HLS, such as, but not limited to, dataflow HLS. For example, in some embodiments, the method includes synthesizing fully-pipelined asynchronous circuits through dataflow high-level synthesis (HLS). In contrast to existing methods and systems, which impose restrictions on pipelining when accessing shared resources, the methods and systems disclosed herein provide fully-pipelined access to shared resources in dataflow circuits.

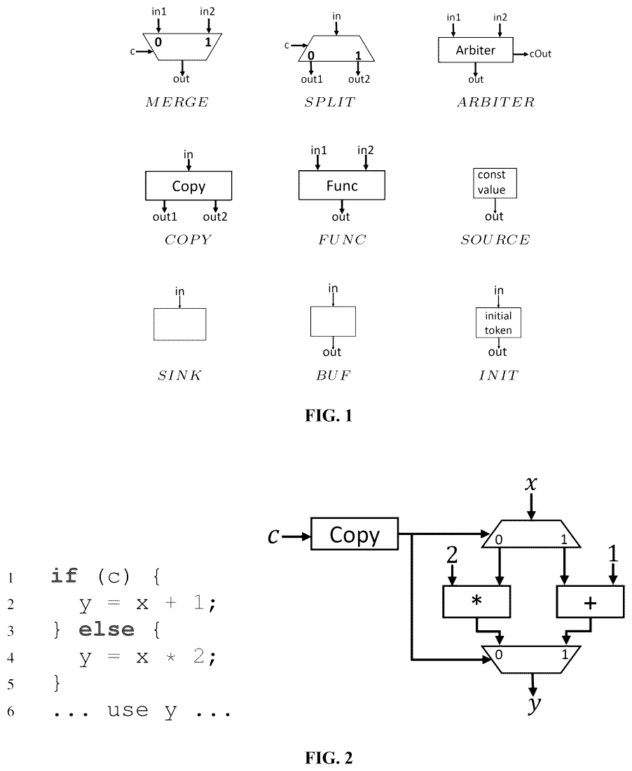

The dataflow circuit includes one or more concurrent, independent dataflow elements. The dataflow elements remain idle until they receive all of the input tokens from their predecessors. Each dataflow element communicates with the predecessors and successors through local handshake protocols, and therefore does not require global control. Suitable dataflow elements include, but are not limited to, one or more of the following elements, which are also illustrated in FIG. 1:

| Element | Function |
|---|---|
| MERGE | Receives a control token from its control port, and an input |
| | data token from the input port specified by the control token, |
| | and sends the received data token on the output port. |
| SPLIT | Receives one input token and sends it to one of the multiple |
| | output ports. The selection is controlled by the control token |
| | received at the control port. |
| ARBITER | Receives the next input token from any one of its input ports, |
| | and sends the received token to the output port. The choice of |
| | input port is non-deterministic. It also generates a control |
| | output token to specify which input has been chosen. |
| COPY | Receives one input token and replicates it to multiple |
| | successors. As soon as one successor is ready, the COPY |
| | sends the received token to it. However, the COPY cannot |
| | receive new input token until all successors have accepted the |
| | old one. |
| FUNC | Receives an input token from each of its inputs, computes |
| | some function (e.g. arithmetic) of the received values, and |
| | sends the result to the output port. |
| SOURCE | Continuously generates token with specified constant value |
| | and sends it to the output port. |
| SINK | Absorbs the received input token. |
| BUF | A one-place FIFO, which can be used to store one data token. |
| INIT | A BUF initialized with a data token (configured during circuit |
| | reset). |

Other than ARBITER, all of the dataflow elements above are deterministic.

In some embodiments, the HLS includes a compilation stage and a linking stage. The compilation stage ignores the function call statements within each function and maps the remaining statements into a separate hardware module. As used herein, the term “hardware module” refers to the building block of the pipelined circuit, which define the block's ports and its internal behavior (e.g., Verilog Module). In such embodiments, since there are no function calls involved, the compilation stage maps different functions into independent circuit blocks. Additionally, the compilation stage synthesizes dangling ports for each function's input/output (I/O) ports, as well as for the arguments (e.g., x) and return values (e.g., y) involved in the function call if there are any.

Following the compilation stage, the linking stage takes over and handles the function calls. In some embodiments, the linking stage includes connecting the dangling ports synthesized in the compilation stage. For example, the linking stage may include generating “glue” logic to combine the different hardware modules together. In some embodiments, the “glue” logic itself is pipelined dataflow circuit, which enables fully pipelined function calls. Additionally or alternatively, in some embodiments, the linking stage treats both memory blocks and function blocks as shared resource blocks, and handles memory access and function call in a unified way. In some embodiments, the linking stage is built with deterministic dataflow elements, which ensures that the dataflow circuits generated have the property of slack elasticity. Without wishing to be bound by theory, it is believed that this slack elasticity provides a guarantee of correct behavior under a wide range of pipelining options.

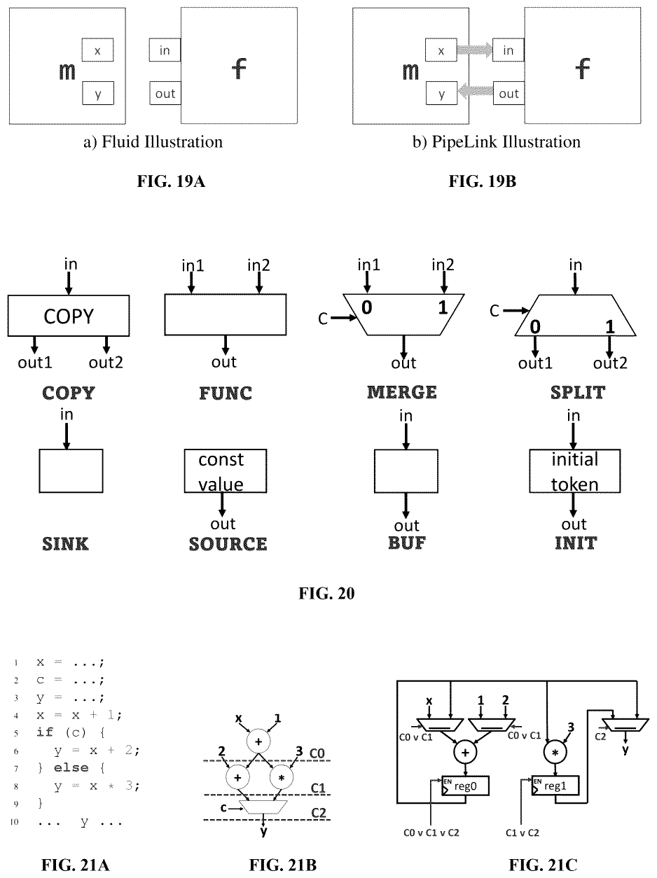

FIGS. 18A-19B illustrate an example of the methods disclosed herein with respect to a full program including multiple functions which can call each other. More specifically, the code shown in FIG. 18A includes two functions m and f. m calls f in the function body, and f is a single-input-single-output function. The compilation stage handles all of the code without the function calls (FIGS. 18B), which is mapped into independent circuits with dangling ports (FIG. 19A). The linking stage, on the other hand, includes only the function calls (FIG. 18C), and involves connecting the dangling ports (FIG. 19B) generated in the compilation stage.

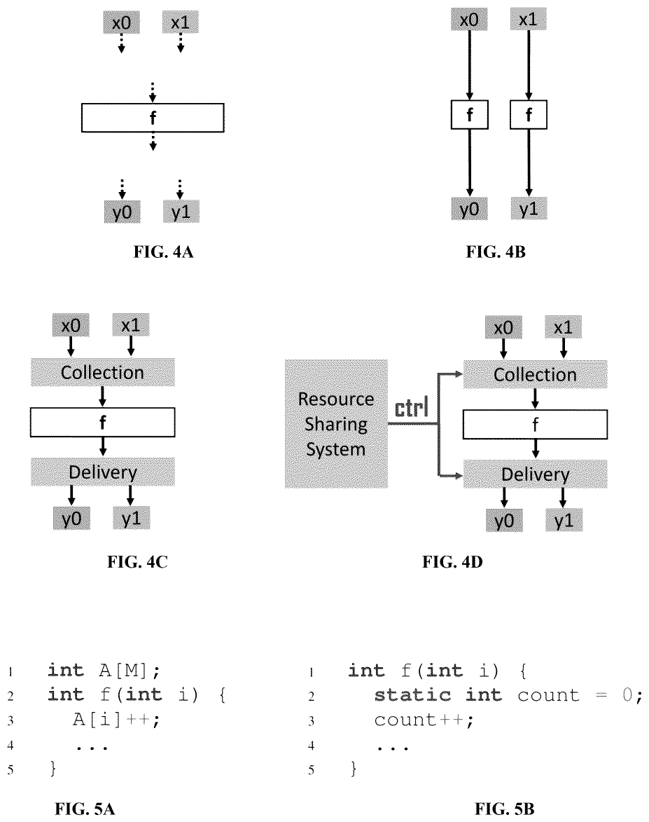

In some embodiments, the methods disclosed herein address the limits of existing solutions for resource sharing for dataflow circuits and enable fully-pipelined resource sharing for dataflow circuits through an adaptive control token network (ACTN). ACTN is a dataflow circuit that correctly computes the control tokens required for pipelined resource sharing (FIG. 4D). First, the ACTN generates a use-resource sequence for each invocation to a function. In some embodiments, the use-resource sequence is a one-bit token stream with a run-length encoded value. The use-resource sequence encodes the number of accesses to a function for the invocation during a run. For example, if the invocation ƒ⁰ accesses the function ƒ three times, the use-resource sequence would be 1,1,1,0. Each “1” enables ƒ⁰ to access f once, and 0 represents the end of accessing f from the specific call site corresponding to the use-resource sequence. Generating the use-resource sequence as discussed herein decouples different invocations from each other such that they do not need to compete for the single shared control token. Second, the ACTN composes different use-resource sequences to control the access order to a shared function. In some embodiments, this includes composing use-resource sequences (corresponding to all call sites of f) together by structural induction on the program to generate the final use-resource sequence and control tokens needed for resource sharing. This provides additional decoupling between control flow and data flow, which reduces the chance of blocking between the control path and the datapath (e.g., FIG. 8).

Based on the syntax of software programs, there are three types of composition: sequential composition, conditional composition, and iterative composition. A sequential composition (SEQ) includes two or more programs composed in a sequential fashion, each program including an invocation to a function (e.g., f). A conditional composition program includes at least one conditional call to a function (e.g., IF_c). An iterative composition includes at least one loop calling a function. As will be appreciated by those skilled in the art, a program may include any combination or lack of composition types.

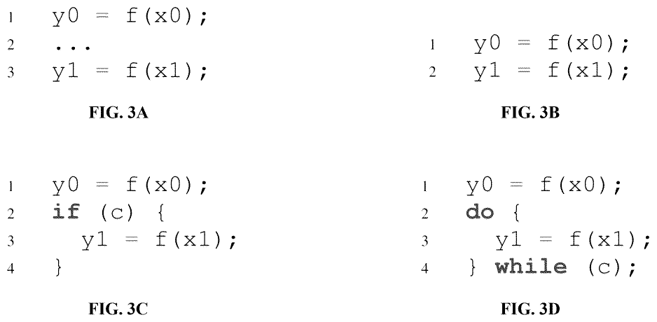

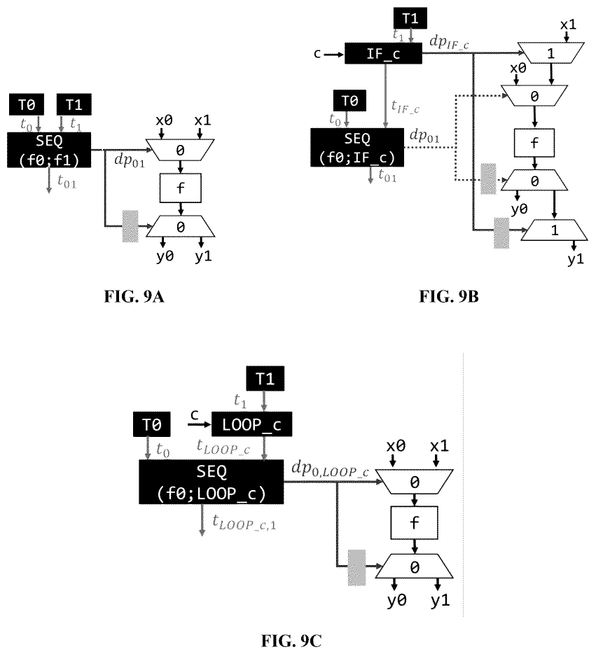

In some embodiments, when the program includes a sequential composition, the method includes introducing a MERGE block to route an argument from the dataflow path to the function; introducing a SPLIT block to route a return value from the function to the dataflow path; computing the use-resource token for the sequential composition from the at least two sub-programs; and generating a control token, the control token routing data tokens through the MERGE and SPLIT blocks. For example, FIG. 3B illustrates a SEQ including two programs composed in a sequential fashion, each program including one invocation of the function f. In such embodiments, as shown in FIG. 9A, two use-resources sequences, t₀ and t₁, are generated for the two invocations. In some embodiments, composing the two programs includes (a) using MERGE/SPLIT to route the arguments/results of f from/to the dataflow circuits, (b) computing the final use-resource sequence t₀₁ from t₀ and t₁, and (c) generating a control token sequence dp₀₁ for the MERGE and SPLIT to route the datapath tokens. Generating the t₀₁ sequence includes reading and propagating 1s from t₀ to the output; switching to t₁ when a 0 is encountered and continuing forwarding 1s from t₁ to the output until a 0 is encountered; and then forwarding the 0 to the output and switching back to t₀. For example, when running the code segment of FIG. 3B once, t₀ is 1,0, t₁ is 1,0 and t₀₁ is 1,1,0. Generating the dp₀₁ sequence includes generating a 0 for each 1 from t₀; and generating a 1 for each 1 from t₁. Referring again to FIG. 3B, the final dp₀₁ would be 0,1.

In some embodiments, when the program includes a conditional composition, the method includes computing the use-resource sequence using the condition. In some embodiments, the method includes introducing a MERGE block to route a conditional argument to the function; introducing a SPLIT block to route a return value according to the conditional argument from the function; computing a conditional use-resource sequence for each conditional branch; computing the use-resource token for the conditional composition from the conditional use-resource sequences; and generating a control token, the control token routing data tokens through the MERGE and SPLIT blocks. For example, in the program if (c) {S} else {T}, where t_{S} and t_{T} are the use-resource sequences for the corresponding branches, the final use-resource sequence is t_{iƒ}, and the datapath control token sequence is dp_{iƒ}. In such embodiments, if c is false, 1s are propagated from t_{T} to t_{iƒ}, and 0s are produced dp_{iƒ} until 0 is encountered. Alternatively, if c is true, 1s are propagated from t_{S} to t_{iƒ}, and 1s are produced for dp_{iƒ} until 0 is encountered. Finally, a 0 is appended to the end of t_{iƒ}. For example, FIG. 9B shows the synthesized circuits for FIG. 3C, where f is invoked twice: ƒ¹ (Line 3) executed in a if block IF_C, and ƒ⁰ (Line 1) and IF_C are executed sequentially. Since ƒ¹ is conditionally invoked, MERGE1 and SPLIT1 are synthesized to conditionally send argument x₁ to f and collect result for y₁, which are controlled by the IF_c network. In general IF_c network takes in three inputs: if condition c, and two use-resource tokens for both branches. (Note that the constant “0” use-resource stream has been omitted as an input to IF_c since f is only used in the true branch.)

In some embodiments, when the program includes an iterative composition, the method includes computing a use-resource token encoding the number of loops in the iterative composition. In some embodiments, the use-resource sequence for the loop body is defined as t_{body}, and the final use-resource sequence is defined as tₗₒₒₚ. In such embodiments, while the loop condition is true, the 1s from t_{body} are propagated to tₗₒₒₚ. When the loop terminates, a 0 is appended to tₗₒₒₚ. The net effect is that tₗₒₒₚ accumulates the 1s from t_{body} in all iterations. Since the loop has a single body, no MERGE/SPLIT or control token generation is needed. For example, in FIG. 3D, f is invoked twice: ƒ⁰ (Line 1) executed in a sequential block, and ƒ¹ (Line 3) executed in a loop block LOOPc. FIG. 9C shows the synthesized circuits.

Using the three building blocks (SEQ, IF_c and LOOP_c), each having fixed functionality and being a pre-designed template circuit, ACTN is dynamically constructed based on the induction of program structures. Each basic type of token network receives input control tokens from base-case generators or other sub-token networks, and generates one output control token. In addition, SEQ and IF_c also generate datapath control tokens along with split/merge data routing logic. The use-resource token network operates in parallel with the datapath. In some embodiments, to reduce stalls in the use-resource network, first in, first out (FIFO) buffers are inserted at the delivery circuit end (e.g., yellow blocks in FIGS. 9A-C). As a result, new datapath control tokens can be generated (thus enabling new invocations to start) without waiting for the previous invocation to finish. The final unused use-resource tokens are connected to a dataflow sink.

For a shared function call to ƒ from g, the use-resource token network is denoted by TN (g,ƒ), the merge tree collection network datapath is denoted by COL(g,ƒ), and the split tree delivery network datapath is denoted by DEL(g,ƒ).

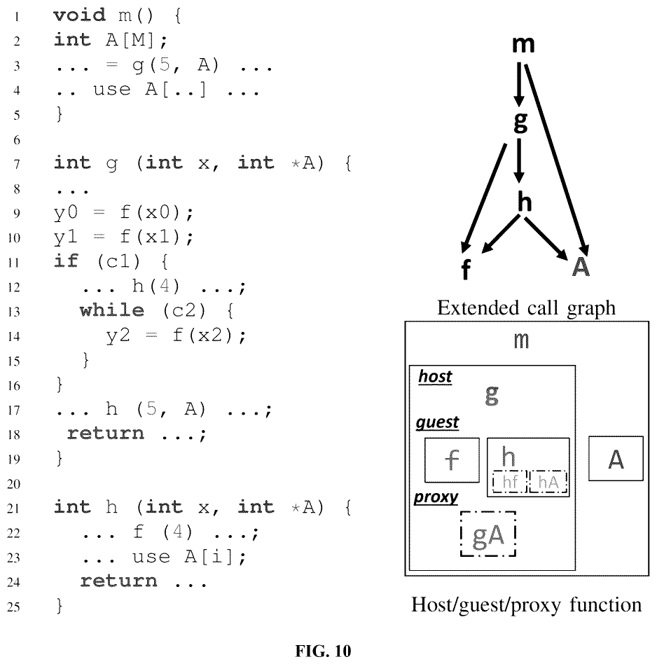

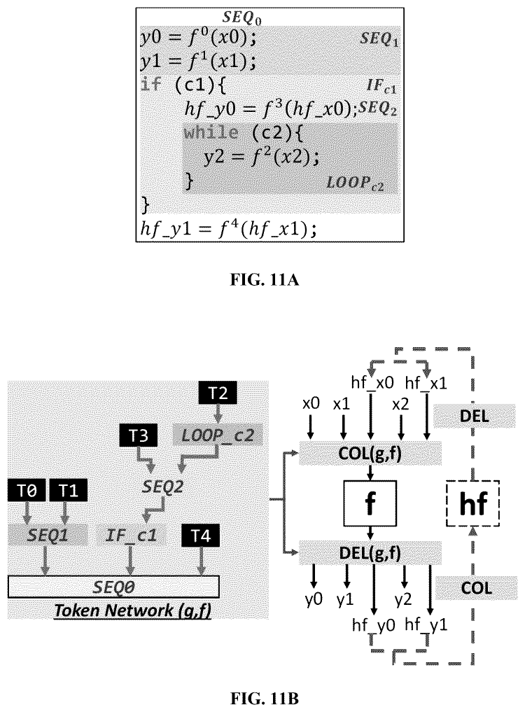

In some embodiments, the methods disclosed herein support a program with multiple functions and/or resource sharing from call sites that can be in different function bodies. For non-recursive programs, the method includes building a directed acyclic call graph for the complete program with the top-level function as the root. Additionally, the call graph is augmented with the names of arrays (i.e., memory) and accesses to memory, since memories and shared functions are treated in a unified fashion. This is referred to herein as the extended call graph. For example, FIG. 10 shows a program and its extended call graph. m is the function to be translated into a dataflow circuit, and it directly accesses array A and calls g. g calls ƒ and h. These relationships are captured by the extended call graph, with the whole program dataflow graph being constructed in two stages (i.e., compilation and linking), as discussed herein.

Following the mapping of each function to a dataflow circuit, where shared function calls within the body of the function are resolved as described herein, any resource access request (to memories and other functions) remains unresolved as “dangling” dataflow connections (i.e., ports) across functions. The resource access requirements are collected across the extended call graph of the program during linking to construct the pipelined linking circuit and complete the dataflow graph. Since memories and ordinary functions are treated in a uniform way, unless otherwise specified herein, the term “function” is used to denote both regular functions and memory banks. Memory blocks in the extended call graph can come from explicitly declared arrays (local or global), as well as dynamically allocated arrays (e.g. malloc). In some embodiments, a locally declared memory may become a shared resource when it is passed as an argument to a function.

Each non-root node (e.g., ƒ₁) in the extended call graph has an immediate dominator (e.g., ƒ₂). In this regard, ƒ₁ is referred to as the guest function for ƒ₂, and ƒ₂ is the host function of ƒ₁. This means that all calls to ƒ₁ must be through ƒ₂. The host of a function ƒ is responsible for coordinating access to ƒ's input and output ports. In some embodiments, the function that is the entry point to the original program can serve as the host function. If ƒ₁ calls ƒ₂ either directly or indirectly through another function, there are two cases: (i) hosted calls, when ƒ₁ hosts ƒ₂; or (ii) nested function calls, where ƒ₁ is not the host of ƒ₂. The term nested function call is used herein to refer to a function call that is reachable via the extended call graph, but is not in the body of the function itself.

### Hosted Function Calls

In some embodiments, as illustrated in FIG. 10, a host function (g) hosts a guest function (ƒ). Function g may directly call ƒ and/or indirectly call ƒ via direct calls to other functions. For example, g may call h, which in turn may call ƒ. In such embodiments, a proxy hƒ is introduced for the indirect call of ƒ through h. Any call to h is also treated as a potential call to ƒ via the proxy hƒ. Multiple calls to h from different program points are treated as multiple calls to the proxy, each having a unique access port to ƒ through the proxy. Since g is the host of ƒ, it has direct access to ƒ's I/O ports. The use-resource token network TN(g,ƒ) for ƒ is synthesized as described hereinabove, while the construction is illustrated in FIGS. 11A-B.

FIG. 11A shows an example code for g from FIG. 10, which calls ƒ three times: ƒ⁰,ƒ¹, and ƒ². Moreover, h also accesses ƒ through its proxy function hƒ, which will redirect the access request to g (host function of h). Therefore, g also implicitly calls ƒ through the execution of h, marked as ƒ³ and ƒ⁴ respectively in FIG. 11A. From g's point of view, it calls ƒ at five call sites, and the use-resource token network is constructed from the structure of the program: (ƒ⁰, ƒ¹) in sequential block SEQ1, ƒ² in loop block LOOPc2, (ƒ³, LOOPc2) in sequential block SEQ2 which is inside if block IFc1, and (SEQ1, IFc1, ƒ⁴) in sequential block SEQ0. As illustrated in FIG. 11B, the construction described above will result in two unique access ports for hƒ. The additional logic to route tokens from the proxy hƒ to the appropriate access ports for ƒ is discussed below.

### Nested Function Calls: Incremental Linking

If h has a call to ƒ which it does not host, then h does not have direct access to the I/O ports of ƒ. As discussed above, h creates a proxy function hƒ internally to achieve the invocation. This proxy simply forwards the access request to the host of h. If the host of h also hosts ƒ, then the access can be resolved there via the hosted function call construction. Otherwise, this forwarding process is repeated by h's host until eventually ƒ's host is reached. This process is referred to herein as incremental linking, because the final access circuit for ƒ is incrementally constructed by this forwarding process, which is guaranteed to terminate at ƒ's host (See Examples for proof).

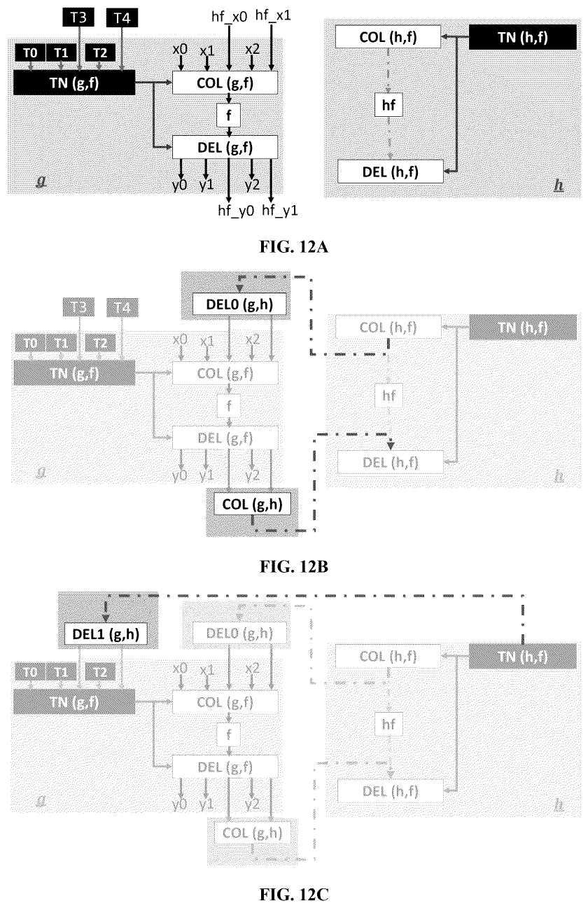

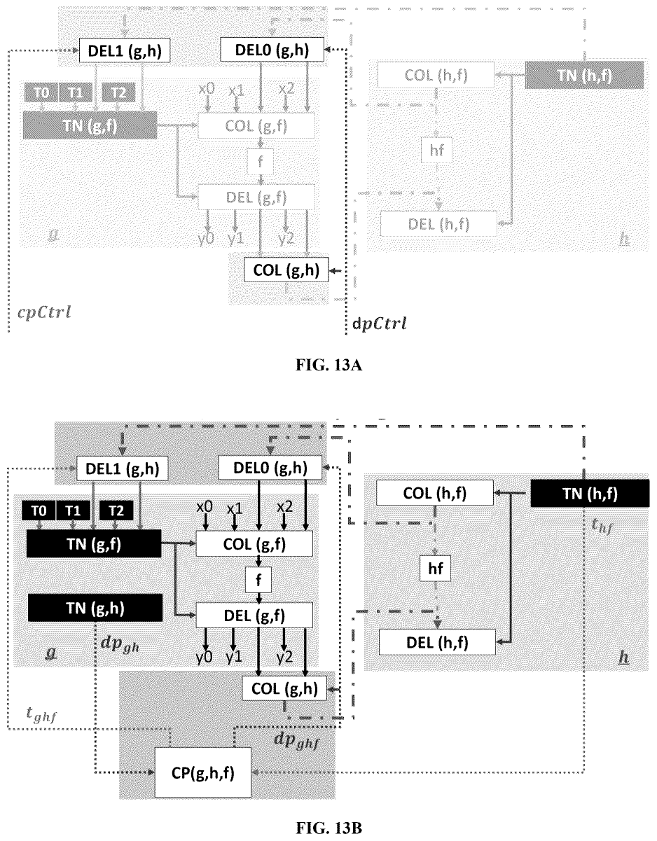

FIG. 10A shows code snippets for the nested invocations, which are handled by the incremental linkers. When the proxy hƒ is used, unique access ports are created for each invocation of hƒ even though hƒ only has a single access port. Accordingly, in some embodiments, the method includes constructing the logic to route data from the proxy function hƒ to each unique access port (FIGS. 12-13). In some embodiments, constructing the logic to route data from the proxy function to the access ports includes receiving input arguments from the proxy at the collection circuit (COL), sending outputs back to the proxy from the delivery circuit (DEL), and generating tokens to represent whether h is currently accessing ƒ or not.

For example, FIG. 12A shows the constructed use-resource token networks and datapaths for both functions g and h. The final access to ƒ is only partially resolved, as there is a proxy function hƒ used for the call site of ƒ within h. g directly/indirectly calls ƒ five times, of which two calls are via the proxy hƒ. The collection circuit COL(g,ƒ) receives two input arguments hƒ x0 and hƒ x1 from hƒ, and the delivery circuit DEL(g,ƒ) sends two outputs hƒ y0 and hƒ y1 back to hƒ. Moreover, the token generators T3 and T4 in TN(g,ƒ) represent whether h is currently accessing ƒ or not. These use-resource token streams are generated from TN(h,ƒ) through the incremental linker according to the following datapath and control.

### 1) Datapath for Incremental Linking:

In some embodiments, the datapath connecting the ports of hƒ to the ports for each call site include: a delivery circuit DEL0(g,h) for routing the arguments for ƒ from hƒ; a delivery circuit DEL1(g,h) for routing the use-resource token stream to T3/T4; and a collection circuit COL(g,h) to route the result from ƒ to the port for hƒ. An example of this datapath is shown in FIGS. 12A-C. More specifically, FIG. 12A shows the generated circuits after g and h are compiled into separate hardware, and TN(g,ƒ) and TN(h,ƒ) have been generated, respectively. Since h does not host ƒ, it accesses hƒ, which has one input/output access port. These ports are connected to the host to access the actual physical ports of the shared function ƒ. g has two call sites for h (Line 8 and Line 13 in FIG. 10), with ports hƒ x0/hf y0 and hƒ x1/hf y1 respectively. When the first (second) call site is active, arguments/results to hƒ are routed to/from the first (second) set of ports. Additionally, the use-resource sequence for hƒ is routed to the appropriate use-resource token stream (T3 or T4).

### 2) Control for Incremental Linking:

FIG. 13A shows the missing control tokens following the introduction of the datapath blocks. Although it would seem natural to use dp_{gh}, the output generated by TN(g,h), to control the datapath blocks DEL0(g,h) and COL(g,h), doing so would not be correct as it would not account for the possibility of repeated (or zero) calls to ƒ from h for a particular invocation. However, information about the number of times ƒ is called from h is available via the use-resource sequence generated by TN(h,ƒ). This sequence can be used to repeat the value dp_{gh} the appropriate number of times. Accordingly, in some embodiments, the control inputs for the datapath blocks include the output generated by TN(g,h), repeated a set number of times according to the use-resource sequence generated by TN(h,ƒ).

Referring to FIG. 10, for example, where h is called twice inside g (marked as h⁰ and h¹ respectively), TN(g,h) will generate dp_{gh} twice, one for h⁰ (marked as dp⁰_{gh}) and one for h¹ (marked as dp¹_{gh}). During the invocation of h⁰, suppose ƒ is invoked twice inside h, then hƒ _x0 (from DEL0(g,h)), hƒ _y0 (for COL(g,h)) and t_{hƒ} (for DEL1(g,h)) are all generated twice while there is only one control token dp⁰_{gh}. This token must be repeated in the appropriate manner to avoid deadlock. A similar issue arises for the invocation of h¹ when ƒ inside h is invoked either more than once or zero times during h¹.

An example Control Path designed for the hierarchical linker is illustrated in FIG. 13B, where CP (g,h,ƒ) is the Control Path for the nested case when g calls h and h calls ƒ. This Control Path has two inputs: dp_{gh} and t_{hƒ}, and generates two output control tokens: dp_{ghƒ} for the datapath token transfer (i.e., for DEL0(g,h) and COL(g,h)) and t_{ghƒ} for the control token transfer (i.e., for DEL1(g,h)). In some embodiments, for example, CP (g,h,ƒ) first receives the data token dp_{gh} indicating which call site for h is next, along with the use-resource. Next, if the use-resource sequence indicates N invocations of hƒ, the token dp_{gh} is sent N times to control the collection and delivery circuits DEL0(g,h) and COL(g,h) (labeled dp_{ghƒ} in FIG. 13B), and the control input to DEL1(g,h) repeats dp_{gh} (N+1) times (labeled t_{ghƒ} in FIG. 13B). Since the use-resource sequences use run-length encoding to represent N, there is one additional use-resource token in t_{ghƒ}.

### Function Pointers

A function pointer can be viewed as a value that determines which access ports of a hardware function block should be accessed. In other words, a function pointer is used to route arguments/return values from/to the caller to/from different functions. In some embodiments, the methods disclosed herein handle data pointers (accessing memories) and function pointers (accessing functions) uniformly.

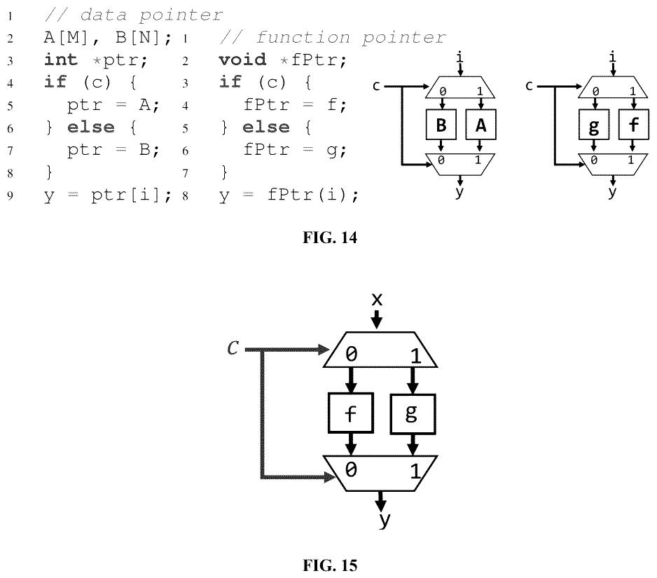

For example, FIG. 14 shows a data pointer example where ptr points to memory bank A (when c is true) and B (when c is false) conditionally. Similarly, it also shows a function pointer example where ƒ Ptr points to function ƒ (when c is true) and g (when c is false) in the same way. In some embodiments, the memory banks and regular function blocks are treated as equal, such that these two programs have exactly the same behavior and the same control and data path may be synthesized for them. The definition and uses of pointers are tracked in the LLVM IR to compute a set of candidate memory targets for each data pointer, and a set of candidate functions for each function pointer. The conditions associated with each binding are also recorded. Each candidate memory/function is assigned an integer index, and this index is used to route data to/from the actual memory/function, while sharing of the memory/function is handled by the unified scheme discussed herein. Accordingly, in some embodiments, the methods disclosed herein are able to handle C++ programs with virtual function dispatch, a program topology that is normally not supported by mainstream HLS tools.

As discussed herein, the presently disclosed methods and systems divide circuit synthesis into a compilation stage where each function is synthesized into separate hardware modules, and a linking stage where the incremental linker generates the “glue” logic to combine the modules into a whole program dataflow graph. This separation of compilation and linking enables incremental compiling of a new function into a circuit and generation of the linking circuit for it without resynthesizing every function again. Additionally, the presently disclosed methods and systems enable an HLS approach where functions are pre-synthesized into a HLS library. Accordingly, the final program can be generated relatively quickly by reusing pre-synthesized logic combined with incremental linking.

Without wishing to be bound by theory, it is believed that the compilation stage of the methods disclosed herein permits handling of complex program structures not currently supported by existing tools, while the linking stage supports pipelined function calls that were previously unavailable. Additionally or alternatively, in some embodiments, the methods and systems disclosed herein provide fully-pipelined memory access, fully-pipelined access to shared function units, function pointers (e.g., through unified handling of the data pointer and function pointer), separate compilation, and/or improved dataflow circuit quality. Furthermore, the method may be implemented on any suitable framework. In some embodiments, for example, the system is implemented on LLVM, which is a widely-used open-source compiler framework. Still further, the methods and systems disclosed herein reduce energy consumption by up to 10 times that of existing commercial tools, provide easier debugging and analysis of the synthesized circuits through unified handling of the function calls and memory access, reduce the time for generation of efficient circuits, and/or support virtual functions through function pointers.

Those skilled in the art will recognize, or be able to ascertain using no more than routine experimentation, numerous equivalents to the specific procedures, embodiments, claims, and examples described herein. Such equivalents were considered to be within the scope of this invention and covered by the claims appended hereto. For example, it should be understood, that modifications in reaction conditions, including but not limited to reaction times, reaction size/volume, and experimental reagents, such as solvents, catalysts, pressures, atmospheric conditions, e.g., nitrogen atmosphere, and reducing/oxidizing agents, with art-recognized alternatives and using no more than routine experimentation, are within the scope of the present application.

It is to be understood that wherever values and ranges are provided herein, all values and ranges encompassed by these values and ranges, are meant to be encompassed within the scope of the present invention. Moreover, all values that fall within these ranges, as well as the upper or lower limits of a range of values, are also contemplated by the present application.

The following examples further illustrate aspects of the present invention. However, they are in no way a limitation of the teachings or disclosure of the present invention as set forth herein.

### EXAMPLES

### Example 1-PipeLink: A Pipelined Resource Sharing System for Dataflow High-level Synthesis

Dataflow high-level synthesis (HLS) is an approach to HLS that maps programs into dataflow circuits. These circuits use distributed control for communication and therefore can be automatically pipelined. However, resource sharing is challenging due to the absence of centralized control. Traditional solutions to this problem impose restrictions on pipelining when accessing the shared resource. Presented herein is PipeLink, a new solution that permits fully-pipelined access to shared resources in dataflow circuits. A complete HLS engine is developed using this approach and asynchronous circuits are used as the target implementation. The engine described herein supports pipelined access to shared function units, as well as pipelined memory access in a unified fashion. Compared to commercial (academic) HLS tools, PipeLink results in 11× (20×) reduction in energy, 1.23× (1.56×) improvement in throughput, 1.22× (1.54×) improvement in latency at a cost of 1.5× (1.08×) increase in area.

### I. Introduction

High-level synthesis (HLS) is a design methodology that automatically maps software programs (e.g, C/C++) into a hardware description language that implements the same functionality. It has received a lot of interests in hardware accelerator design since it can reduce design time and is more accessible to software developers. There are two major categories of HLS: statically scheduled HLS (static HLS) and dataflow HLS. Statically scheduled HLS (Philippe Coussy and Adam Morawiec. High-level synthesis, volume 1. Springer, 2010; Dirk Koch, Frank Hannig, and Daniel Ziener, editors. FPGAs for Software Programmers. Springer, 2016) converts a program into a datapath that contains all the operators from the program and a global state machine that enforces centralized control for these operators. To synthesize the state machine, the static HLS tool needs accurate delay information (in terms of clock cycles) for all operators at synthesis time and uses this information to compute an optimized schedule. This early scheduling may lead to sub-optimal performance, but the central scheduler design makes it good at coordinating different circuit components and managing resource access conflicts.

Dataflow HLS, on the other hand, maps programs into dataflow circuits consisting of concurrent, independent dataflow elements. The dataflow elements communicate with each other through local control (i.e., handshake or ready/valid protocols), so they can be automatically pipelined without requiring global control. However, the lack of global control makes it hard to coordinate the actions of different dataflow elements.

This Example shows that currently both static HLS and dataflow HLS have limitations when faced with the combination of pipelined design and general hardware resource sharing. Additionally, it is shown that current designs lead to sub-optimal and logically non-pipelined circuits for resource sharing. To address this issue, a new way of building a resource sharing system for dataflow HLS is proposed that leverages the program's structure to construct a resource sharing system. This approach permits additional decoupling between control flow and data flow in the hardware, overcoming some of the limitations of previous approaches.

The techniques are implemented in PipeLink, an HLS engine that enables pipelined resource sharing in dataflow circuits. PipeLink makes a number of contributions to dataflow HLS: (i) it includes a general pipelined resource sharing mechanism that supports fully-pipelined resource sharing in dataflow circuits; (ii) it supports both pipelined function calls and pipelined memory accesses in a unified design; (iii) it implements a range of dataflow graph optimizations that improve the quality of the final dataflow graph implementation. This HLS approach is evaluated against both academic and commercial HLS tools. Overall, PipeLink provides significant improvement in energy, some improvement in latency and throughput while paying some area penalty.

### II. Background

### A. Dataflow Circuits

Dataflow circuits consist of concurrent, independent dataflow elements. Each dataflow element communicates with the predecessors and successors through local handshake protocols, thus it does not require global control. A dataflow element remains idle until it receives input tokens from its predecessors (Jack B. Dennis. The evolution of ‘static’ data-flow architecture. In J.-L. Gaudiot and L. Bic, editors, Advanced Topics in Data-Flow Computing. Prentice-Hall, 1991). There are nine commonly used dataflow elements shown in FIG. 1.
MERGE: it receives an control token from its control port, and an input data token from the input port specified by the control token, and sends the received data token on the output port.
SPLIT: it receives one input token and sends it to one of the multiple output ports. The selection is controlled by the control token received at the control port;
ARBITER: it receives the next input token from any one of its input ports, and sends the received token to the output port. The choice of input port is non-deterministic. It also generates a control output token to specify which input has been chosen;
COPY: it receives one input token and replicates it to multiple successors. As soon as one successor is ready, the COPY sends the received token to it. However, the COPY cannot receive new input token until all successors have accepted the old one;
FUNC: it receives an input token from each of its inputs, computes some function (e.g. arithmetic) of the received values, and sends the result to the output port;
SOURCE: it continuously generates token with specified constant value and sends it to the output port;
SINK: it absorbs the received input token;
BUF: it is a one-place FIFO, which can be used to store one data token;
INIT: it is a BUF initialized with a data token (configured during circuit reset);

All of these dataflow elements except ARBITER are deterministic. PipeLink is built with deterministic dataflow elements. This is sufficient to ensure that the dataflow circuits generated have the property of slack elasticity, which provides a theoretical guarantee of correct behavior under a wide range of pipelining options (Rajit Manohar and Alain J. Martin. Slack elasticity in concurrent computing. In Johan Jeuring, editor, Mathematics of Program Construction, pages 272-285, Berlin, Heidelberg, 1998. Springer Berlin Heidelberg).

Consider the iƒ example in FIG. 2. x is used for addition in the true branch, it is used in a multiplication in the false branch. y is redefined in both branches. When the code is mapped into dataflow circuit, two FUNCs are synthesized (for + and for *) for the computation, along with SOURCEs for constant operands. A SPLIT is synthesized to conditionally propagate x into the corresponding FUNC for computation based on the condition c. A MERGE is synthesized to conditionally select from token y₀ and y₁ based on c. Lastly, control token c is passed to COPY which connects to the control ports of the MERGE and SPLIT.

As pointed out by existing works, dataflow circuits can be automatically pipelined. In this example, x is sent to the correct FUNC based on c, and the FUNC will send its result to the MERGE immediately when the computation is done; the whole process is data-driven, without requiring centralized (global) control.

### B. Resource Sharing Problem for HLS

In software programs, function calls and memory accesses (from explicitly declared arrays and dynamically allocated memories) are pervasive, and the corresponding functions and memories are shared among different callers. An HLS tool has the choice of inlining functions at each call site, or having a single hardware block for the function that is shared by the call sites, or some combination. However, memory banks/global memory has to be viewed as a shared resource.

For the purposes of studying the resource sharing problem, a memory can be viewed in the same way as a function. A memory has input ports for address, read/write command, and data (used for write operations), and an output port that produces data (used for read operations), so memory access can be treated as a special type of function call where the function cannot be inlined/replicated. In this Example, “function” is used to denote both regular functions and memory banks, and the system supports both in a unified way.

To start with, FIG. 3A shows a program segment where f is invoked twice. Suppose f is a single input, single output function, and it has two callers y₀ and y₁. Let's annotate the two invocations to f as ƒ⁰ and ƒ¹ respectively. Furthermore, let's assume f is not inlined, so it is a shared function. f is synthesized as an independent hardware block, and its in/output ports as well as x0, x1, y0 and y1 are synthesized as dangling ports, as illustrated in FIG. 4A. The HLS tool needs to synthesize a resource sharing system to send x0 and x1 to f and propagates the result from f to y0 and y1 respectively.

The access order to f is important. Each invocation could have side-effects: f could modify memory (FIG. 5A), or update static variables (FIG. 5B). To guarantee correctness, it is important to make sure f is accessed in the same order as the original software program.

Furthermore, the number of accesses to f for each invocation is unknown during static synthesis stage. Instead, it needs to be dynamically computed based on runtime conditions. For example, FIG. 3A shows a code segment of two invocations to f. For sequential invocation (FIG. 3B), ƒ⁰ and ƒ¹ each access f once. For conditional invocation (FIG. 3C) where c is false during a specific run, ƒ¹ should not access f. For iterative invocation (FIG. 3D) where the loop has N iterations during a specific run, ƒ¹ should access f N times before the next invocation of f.

To summarize, the resource sharing system needs to:
1) enforce the access order to f to be the same as specified by the programs; for example, x0 should be sent to f before x1 (FIG. 5A);
2) count the number of accesses to f for each invocation, and starts the next invocation only when the current one has finished using f;

Note that because the original software program is sequential, all of the information necessary to determine the ordering and access count is available at run-time; the challenge is to compute it using dataflow operators.

### C. Resource Sharing Options

The following summarizes different options for addressing the resource sharing problem in HLS, including both existing approaches and the presently proposed approach.

### 1) Replication

If f is inlined, then the resource sharing problem is automatically solved by replicating the resources of f at each call site, as shown in FIG. 4B. This is the default options for the commercial HLS tools as well as academic HLS tools. This solution can dramatically increase the circuit cost if the shared functions are expensive. Furthermore, this approach cannot be used for memories that are accessed from more than one program location.

### 2) Blocking Sharing

As shown in FIG. 4C, the HLS engine should synthesize a collection circuit to collect and select the arguments to f from all callers, as well as a delivery circuit to deliver the results back to the appropriate caller. In the blocking approach, there is a lack of explicit control to coordinate the access order to f; hence, access to f is granted on a first-come first-served basis. However, the order in which access to f is requested must match the software program order whenever f has side effects (e.g., FIGS. 5A-B). This means that if the underlying HLS implementation has any pipelining, extra logic is needed to guarantee that this access ordering is preserved. This applies to both accesses from different call sites, as well as repeated accesses from a fixed call site. Without extra logic, this would violate the requirements for accessing the shared resource (Section II-B).

To handle both these issues, existing solutions require that f is shared in a blocking fashion, i.e., x1 cannot be generated and sent to f until f receives x0 and produces y0. An alternate approach is to only have blocking on the collection logic end, and generate a control token in the collection logic that is used to route the results to the appropriate invocation (Lana Josipovic, Andrea Guerrieri, and Paolo Ienne. Invited tutorial: Dynamatic: From C/C++ to dynamically scheduled circuits. In Stephen Neuendorffer and Lesley Shannon, editors, FPGA '20: The 2020 ACM/SIGDA International Symposium on Field-Programmable Gate Arrays, Seaside, CA, USA, Feb. 23-25, 2020, pages 1-10. ACM, 2020). For example, if x0 is selected, then a control token 0 can be generated by the collection circuit and routed to the delivery logic, which then can route the result to y0; the ARBITER dataflow element can be used for this purpose. However, access to the collection circuit is still blocking. In particular, in the pipelined context, the next x0 invocation must block until all possible future invocations from the current execution have been considered. Furthermore, using an ARBITER means that slack elasticity is no longer guaranteed, and hence some of the dataflow optimizations described in Section V may not be usable. Described below is a representative blocking mechanism from the literature.

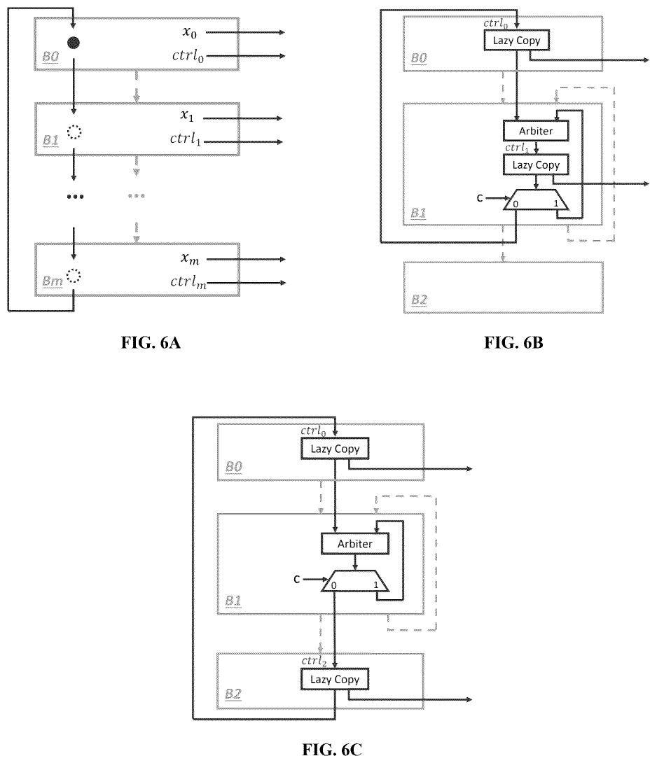

Token-based mutual exclusion network (Alain J. Martin. Distributed mutual exclusion on a ring of processes. Science of Computer Programming, 5:265-276, 1985). This is an example of blocking resource sharing. In this approach, a single token is used to dynamically track the activated basic block as the program executes, and a shared function call is only permitted from the currently active block. The general structure is shown in FIG. 6A. The gray blocks represent the control flow graph of the software program, where the left branch is the false branch and the right branch is the true branch, and the gray dashed line represents the control dependencies among them. The red ball represents the control token in the graph, and the red line represents the flows of the control token. The solid ball denotes its current location (i.e., the currently activated basic block), and the dashed balls denote its potential future locations. Since at most one basic block will become active, there is only one active copy of the control token in the graph, so these control token generation sites are mutually exclusive.

Suppose B0 is currently activated, and the control token stays in B0. Suppose B0 has such an invocation: y0=f(x0). Since B0 is active, x0 can be sent to f together with the control token for computation. If B0 has multiple invocations to f, they can access f in a round robin manner. Note that if B0 also tries to access another function g, then two unique control tokens will be generated separately, one for f and one for g.

FIG. 6B shows how the control token is propagated across basic blocks based on the example in FIG. 3D. The program's control flow graph is simplified so that it has three basic blocks: B0 is the enter block, B1 is the loop block and B2 is the end block. There are two invocations to f: ƒ⁰ happens in B0, and ƒ¹ happens in B1. Since B0 is the enter block, the control token resides in B0 initially, denoted as ctrl₀. It is sent to a LAZY COPY dataflow element, which has similar functionality to the COPY element except that if one of its output ports is stalled, the other output ports are stalled as well. This LAZY COPY element has two successors: one to the collection circuit for ƒ⁰ to take action, and one to the token network in B1. While ƒ⁰ is accessing f, one output port of the LAZY COPY element is stalled, so the control token will not flow into B1. When ƒ⁰ has passed x0 to f, the output port of LAZY COPY element is un-stalled, and the control token will flow into B₁.

At the top of B1, it has an ARBITER to receive B0's control token and generates its own control token ctrl₁, which is then sent to a LAZY COPY element. One of its output is used for ƒ¹ to access f, and the other output connects to a SPLIT, so if the loop condition c is true, the control token will be routed back to the ARBITER for the next iteration. When the loop finishes and c becomes false, the control token is routed back to the entry block B0 for the next run.

The token network routes one control token across basic blocks as program executes, and the control token has similar functionality as program counter, except that it tracks program execution at the basic block level (instead of instruction level). While this design enables pipelined function calls within the currently activated basic block in program's control flow graph, it tightly couples control token generation with the datapath computation as well as prevents pipelined access across basic blocks. In the example in FIG. 6A, the next execution of block B0 would be stalled waiting for the previous execution of block Bm, waiting for access to the mutual exclusion token.

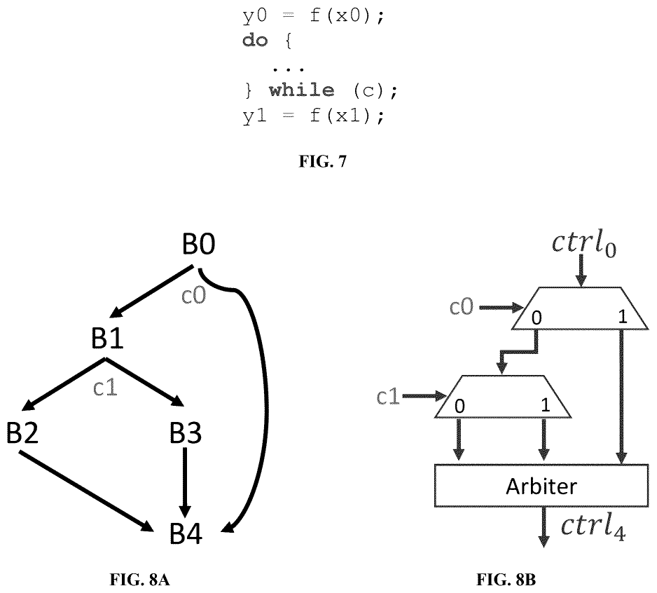

The new token network is illustrated in FIG. 6C. In this example, the second invocation ƒ¹ happens in B2, which is after the loop block B1 (FIG. 7). Suppose x1 is not updated in the loop, then after ƒ⁰ sends x0 to f, it is already OK for ƒ¹ to send x1 to f for pipelined function call. However, after ctrl₀ is used in B0, it enters into the loop block B1 and is routed repeatedly inside B₁. When the loop finishes, ctrl₁ can be generated and ƒ¹ can then start to send x1 to f. In this example, ƒ¹ has to wait for the loop to finish even though x1 has no data dependency with the loop.

### Example 2

FIG. 8A shows a program's control flow graph. Suppose there are two invocations to f in B0 and B4 respectively, and the distributed token network is shown in FIG. 8B. The whole graph (i.e., B0, B1, B2, B3, B4, B5) will become non-pipelined completely. Whenever B0 is activated, it requires the control token ctrl₀ to access f, but there is only one copy of the control token in the whole graph, and it will not be routed back until it reaches the end of the whole graph.

The solution discussed herein solves these problems, and it is shows that PipeLink can easily support pipelined function calls in these scenarios.

### 3) Pipelined Sharing

FIG. 4D shows the pipelined resource sharing system for f, which explicitly calculates the ctrl tokens required by Section II-B. The benefit of this approach is that the control generation is decoupled from the data tokens, and often can be computed earlier since it only depends on the control flow of the program.

Static HLS solution. Static HLS generates a global state machine to provide central control to all operations in the circuits, so it can easily generate the desired ctrl tokens for the resource sharing system. However, in order to generate a pipelined hardware block for f, it is essential to decide the initial interval (II) for f during static synthesis stage. To do that, it is often required to inline the sub-functions and unroll all the loops inside f (Cadence hls, Legup directive, Vivado hls), which can result in high circuit overhead. In addition, static HLS approaches do not optimize for two common cases:
1) Conditional executions in f: FIG. 2 shows a iƒ statement with the true branch doing addition and the false branch doing multiplication. Static HLS has to consider the worst-case scenario and use the multiplication delay to represent the if statement delay. If f has nested, unbalanced iƒ/switch statements, this problem gets worse;
2) Early-return in f: Sometimes a function will return in the middle of the function body for fast computation. For example, f could return immediately if input argument x equals to 0. However, the static HLS has to consider the whole function body when calculating the II, completely ignoring this shortcut. If this early return is the common case, then this results in sub-optimal pipelining.

In practice, pipelined resource sharing in static HLS is only enabled under user's discretion (typically via #pragma directives in C/C++) due to its potential for introducing high overhead.

Dynamic HLS solution. Without wishing to be bound by theory, it is believed that the disclosure herein presents the first solution to the problem of pipelined resource sharing for dataflow circuits that are generated from programs. This solution results in a purely deterministic dataflow implementation, ensuring slack elasticity and hence freedom to apply aggressive dataflow optimizations. As a result, the approach disclosed herein supports pipelined resource sharing for dynamically scheduled dataflow HLS. Although it is well-known that it is challenging to solve the control token generation problem in the general case (Arvind. Dataflow: passing the token. Keynote address, International Symposium on Computer Architecture (ISCA)); the discussion herein shows how this problem is tackled.

### D. Summary

In order to implement a pipelined function call, the resource sharing system needs to control the access order as well as the number of accesses among different invocations. This requires coordination among multiple independent callers.

The static HLS seems to be a natural fit since it synthesizes a global state machine to provide centralized control for the whole circuit, but it has to statically calculate the II of f in order to share it in a pipelined manner. Calculating II requires accurate timing information of f. As a result, the static HLS has to unroll loops, inline sub-functions and consider the worst-case scenario for conditional executions. This often incurs high overhead, so function pipelining is only enabled under user's careful discretion.

The dataflow HLS can synthesize automatically pipelined circuits without requiring timing information of circuit components during synthesis. However, the lack of centralized control makes it hard to control the concurrent accesses to the shared resource. Distributed token network tries to construct a “global state machine” in a distributed manner and use one control token to track the currently activated basic block. This design seems to perfectly match the control token requirements Section II-B, but it tightly couples the control token generation with the datapath logic, and could block the datapath unnecessarily and reduce the level of pipelining of the circuit.

### III. Adaptive Control Token Network

The solution described herein to the pipelined resource sharing problem is the Adaptive Control Token Network (ACTN). ACTN addresses the limits of the distributed token network and enables fully-pipelined resource sharing for dataflow circuits. ACTN is a dataflow circuit that correctly computes the control tokens required for pipelined resource sharing (FIG. 4D).

Consider the example in FIG. 3D, where f is invoked twice, and the second invocation happens inside a loop statement. FIG. 9C shows the control path and datapath. A pair of MERGE and SPLIT are synthesized to route the datapath tokens, and their behaviors are controlled by the control tokens. The first control token should be ( ) to route x₀ to f. Then, suppose the loop runs for N iterations, then x₁ would be regenerated for N times (Rui Li, Lincoln Berkley, Yihang Yang, and Rajit Manohar. Fluid: An asynchronous high-level synthesis tool for complex program structures. In 27th International Symposium on Advanced Research in Asynchronous Circuits and Systems (ASYNC 2021), 2021), and the control tokens should be 1~1/N to route the N copies of x₁ to ƒ. ACTN can capture the control structure of the program as well as runtime conditions to compute the control tokens.

First, it generates a use-resource sequence for each invocation to serve as its private control token stream and resource access counter, so different invocations are decoupled from each other and do not need to compete for the single shared control token. Second, it composes different use-resource sequences to control the access order to the shared function ƒ. It provides additional decoupling between control flow and data flow, which reduces the chance of blocking between the control path and the datapath (e.g., FIGS. 8A-B).

### A. The “Use-Resource” Sequence

A use-resource sequence is generated for each invocation to ƒ. It encodes the number of accesses to f for the invocation during current run. It is a one-bit token stream whose value is run-length encoded. For example, if the invocation ƒ⁰ accesses f three times, the use-resource sequence would be 1,1,1,0. Each “1” enables ƒ⁰ to access f once, and 0 represents the end of accessing f from the specific call site corresponding to the use-resource sequence. Construction of this sequence from the structure of the program is now described.

### B. The Base Case: A Single Function Call

The base case corresponds to a single function call invocation. The use-resource sequence for this case is simply 1,0, meaning this invocation would access f exactly once when the program reaches this call site.

### C. Composing Use-Resource Sequences

ACTN composes use-resource sequences (corresponding to all call sites of f) together by structural induction on the program to generate the final use-resource sequence and control tokens needed for resource sharing. Based on the syntax of software programs, there are three types of composition: sequential composition, conditional composition and iterative composition.

Sequential composition: SEQ. Consider the example in FIG. 3B where two programs are composed in a sequential fashion and both include one invocation to f. As shown in FIG. 9A, there have two use-resources sequences, t₀ and t₁, generated for the two invocations.²

To compose the two programs: (a) MERGE/SPLIT is used to route the arguments/results of f from/to the dataflow circuits. (b) the final use-resource sequence t₀₁ is computed from t₀ and t₁. (c) a control token sequence dp₀₁ is generated for the MERGE and SPLIT to route the datapath tokens.

SEQ network generates t₀₁ as follows: 1s from t₀ are read and propagated to the output; when a 0 is encountered, SEQ switches to t₁ and continues forwarding 1s from t₁ to the output until a 0 is encountered. Then, SEQ forwards the 0 to the output, and switches back to t₀. If the code segment in FIG. 3B is run once, t₀ is 1,0, t₁ is 1,0 and t₀₁ is 1,1,0.

dp₀₁ sequence is generated as follows: for each 1 from t₀, a 0 is generated; for each 1 from t₁, a 1 is generated. The final dp₀₁ is 0.1 for this example.

Conditional composition: IF_c. If f is called in a conditional statement where c is the condition, then the use-resource sequence can be computed using c. Suppose the following program: if(c) {S} else {T}, and t_{S} and t_{T} are the use-resource sequences for the corresponding branches. The final use-resource sequence is t_{iƒ}, and the datapath control token sequence is dp_{iƒ}.

If c is false, 1s is propagated from t_{T} to t_{iƒ} and produces 0s for dp_{iƒ} until 0 is encountered. If c is true, 1s is propagated from t_{S} to t_{iƒ} and produces 1s for dp_{iƒ} until 0 is encountered. In the end, a 0 is appended to the end of t_{iƒ}.

In FIG. 3C, f is invoked twice: ƒ¹ (Line 3) executed in a if block IF_C, and ƒ⁰ (Line 1) and IF_C are executed sequentially. FIG. 9B shows the synthesized circuits. Since ƒ¹ is conditionally invoked, MERGE1 and SPLIT1 are synthesized to conditionally send argument x1 to f and collect result for y1, which are controlled by the IF_c network. In general IF_c network takes in three inputs: if condition c, and two use-resource tokens for both branches. (Note that the constant “0” use-resource stream has been omitted as an input to IF_c, since f is only used in the true branch.)

Iterative composition: LOOP_c. The loop case is similar to the conditional case. Suppose the use-resource sequence for the loop body is t_{body}, and the final use-resource sequence is tₗₒₒₚ.

While loop condition is true, the 1s from t_{body} are propagated to tₗₒₒₚ. When the loop terminates, a 0 is appended to tₗₒₒₚ. The net effect is: tₗₒₒₚ accumulates the 1s from t_{body} in all iterations. Since the loop has a single body, no MERGE/SPLIT or control token generation is needed.

In FIG. 3D, f is invoked twice: ƒ⁰ (Line 1) executed in a sequential block, and ƒ¹ (Line 3) executed in a loop block LOOPc. FIG. 9C shows the synthesized circuits.

### D. Summary

There are three building blocks used to construct ACTN: SEQ, IF_c and LOOP_c. Each building block has fixed functionality, and is pre-designed template circuit. ACTN is dynamically constructed based on the induction of program structures. Each basic type of token network receives input control tokens from base-case generators or other sub-token networks, and generates one output control token. In addition, SEQ and IF_c also generate datapath control tokens along with split/merge data routing logic. The use-resource token network operates in parallel with the datapath. To reduce stalls in the use-resource network, FIFO buffers are inserted at the delivery circuit end (shown as yellow blocks in FIGS. 9A-C). As a result, new datapath control tokens can be generated (thus enabling new invocations to start) without waiting for the previous invocation to finish. The final unused use-resource tokens are connected to a dataflow sink.

For a shared function call to ƒ from g, the use-resource token network is denoted by TN (g,ƒ), the merge tree collection network datapath by COL(g,ƒ), and the split tree delivery network datapath by DEL(g,ƒ).

### IV. Static Dataflow Synthesis

With the techniques described in the previous section, pipelined resource sharing can be handled within the body of a function. This section describes how the present design is extended to support a program with multiple functions, and the problem of resource sharing from call sites that can be in different function bodies. Attention is restricted to non-recursive programs, similar to other HLS tools.

Since the program is assumed to be non-recursive, a directed acyclic call graph can be built for the complete program with the top-level function as the root. In addition, the call graph is augmented with the names of arrays (i.e. memory) and accesses to memory, since memories and shared functions are treated in a unified fashion. This is called the extended call graph.

FIG. 10 shows a program and its extended call graph. m is the function to be translated into a dataflow circuit, and it directly accesses array A and calls g. g calls f and h. These relationships are captured by the extended call graph (FIG. 10). PipeLink constructs the whole program dataflow graph in two stages that are viewed as compilation and linking.

During compilation stage, each function is mapped to a dataflow circuit using existing techniques (Rui Li, Lincoln Berkley, Yihang Yang, and Rajit Manohar. Fluid: An asynchronous high-level synthesis tool for complex program structures. In 27th International Symposium on Advanced Research in Asynchronous Circuits and Systems (ASYNC 2021), 2021; John Teifel and Rajit Manohar. Static tokens: Using dataflow to automate concurrent pipeline synthesis. In 10th International Symposium on Advanced Research in Asynchronous Circuits and Systems (ASYNC 2004), 19-23 Apr. 2004, Crete, Greece, pages 17-27. IEEE Computer Society, 2004). Shared function calls within the body of the function are resolved as described in the previous section. Hence, any resource access request (to memories and other functions) remains unresolved as “dangling” dataflow connections (i.e. ports) across functions. During linking, PipeLink collects the resource access requirements across the extended call graph of the program to construct the pipelined linking circuit and complete the dataflow graph.

As previously mentioned, PipeLink treats memories and ordinary functions in a uniform way, and “function” is used to denote both regular functions and memory banks unless otherwise specified. Memory blocks in the extended call graph can come from explicitly declared arrays (local or global), as well as dynamically allocated arrays (e.g. malloc). Note that a locally declared memory might become a shared resource when it is passed as an argument to a function.

Each non-root node ƒ₁ in the extended call graph has an immediate dominator ƒ₂; ƒ₁ is the guest function for ƒ₂, and ƒ₂ is the host function of ƒ₁. This means that all calls to ƒ₁ must be through ƒ₂. In the worst-case, the function that is the entry point to the original program can serve as the host function. In PipeLink the host of a function ƒ is responsible for coordinating access to ƒ's input and output ports.

If ƒ₁ calls ƒ₂ either directly or indirectly through another function, there are two cases: (i) hosted calls, when ƒ₁ hosts ƒ₂; or (ii) nested function calls, where ƒ₁ is not the host of ƒ₂. The term nested function call is used to refer to a function call that is reachable via the extended call graph, but is not in the body of the function itself.

### A. Hosted Function Calls

In FIG. 10, g hosts guest function ƒ. Function g may directly call ƒ, and may also indirectly call ƒ via direct calls to other functions. In the present example, g may call h which in turn may call ƒ. A proxy hƒ is introduced for the indirect call of ƒ through h. Any call to h is also treated as a potential call to ƒ via the proxy hƒ. Multiple calls to h from different program points are treated as multiple calls to the proxy, each having a unique access port to ƒ through the proxy.

Since g is the host of ƒ, it has direct access to ƒ's I/O ports. PipeLink synthesizes the use-resource token network TN(g,ƒ) for f as described in Section III. FIGS. 11A-B illustrate the construction, discussed in detail next.

FIG. 11A shows an example code for g from FIG. 10, which calls ƒ three times: ƒ⁰ (line 5), ƒ¹ (line 6) and ƒ² (line 10). Moreover, h also accesses ƒ through its proxy function hƒ, which will redirect the access request to g (host function of h). Therefore, g also implicitly calls ƒ through the execution of h (Line 8 and 13), marked as ƒ³ and ƒ⁴ respectively in FIG. 11A.

From g's point of view, it calls ƒ at five call sites, and the use-resource token network is constructed from the structure of the program: (ƒ⁰, ƒ¹) in sequential block SEQ₁, ƒ² in loop block LOOP_{c2}, (ƒ³, LOOP_{c2}) in sequential block SEQ₂ which is inside if block IF_{c1}, and (SEQ₁, IF_{c1}, ƒ⁴) in sequential block SEQ₀. This is shown in in FIG. 11B.

Note that the construction from Section III will result in two unique access ports for hƒ as illustrated in FIG. 11B. Additional logic is needed to route tokens from the proxy hƒ to the appropriate access ports for ƒ. This construction is discussed in detail in the following section.

### B. Nested Function Calls: Incremental Linking

If h has a call to ƒ which it does not host, then h does not have direct access to the I/O ports of ƒ. As discussed above, in order to achieve the invocation, h creates a proxy function hƒ internally. This proxy simply forwards the access request to the host of h. If the host of h also hosts ƒ, then the access can be resolved there via the construction in Section IV-A. Otherwise, this forwarding process is repeated by h's host until eventually ƒ's host is reached. This process is called incremental linking, because the final access circuit for ƒ is incrementally constructed by this forwarding process. The forwarding process is guaranteed to terminate at ƒ's host because of the following result:

Theorem 1. If ƒ₁ (hosted by m₁) calls ƒ₂ (hosted by m₂), and if ƒ₁ does not host ƒ₂, then m₂=m₁, or m₂ dominates m₁ in the extended call graph.

Proof. The entry node is marked in the extended graph ENTRY. Suppose m₂ does not dominate or equal to m₁, then there exists a path for ENTRY→m₁ without going through m₂, noted as path₁. m₁ hosts ƒ₁, so there exists a path for m₁→ƒ₁. ƒ₁ calls ƒ₂, so there is a path for ƒ₁→ƒ₂. Consider the path path₁→ƒ₁→ƒ₂, it starts from ENTRY and ends at ƒ₂ without going through m₂, which contradicts with the assumption that m₂ hosts ƒ₂. Therefore, m₂ dominates or equals to m₁.

FIG. 10 shows code snippets for the nested invocations, which are handled by the incremental linkers. When the proxy hƒ is used, unique access ports are created for each invocation of hƒ even though hƒ only has a single access port. Hence, PipeLink must construct the logic to route data from the proxy function hƒ to each unique access port. This design is detailed next, and illustrate each step of the construction in FIGS. 12A-13B.

FIG. 12A shows the constructed use-resource token networks and datapaths for both functions g and h, constructed according to Section III. Note that the final access to ƒ is only partially resolved, as there is a proxy function hƒ used for the call site of ƒ within h. g directly/indirectly calls ƒ five times, of which two calls are via the proxy hƒ.

The collection circuit COL(g,ƒ) receives two input arguments hƒ x0 and hƒ x1 from hƒ, and the delivery circuit DEL(g,ƒ) sends two outputs hƒ y0 and hƒ y1 back to hƒ. Moreover, the token generators T3 and T4 in TN(g,ƒ) represent whether h is currently accessing f or not; those use-resource token streams must also be appropriately generated from TN(h,ƒ). How these token streams are generated by PipeLink's incremental linker to complete the circuit is described now.

### 3) Datapath for Incremental Linking:

FIG. 12A shows the generated circuits after PipeLink compiles g and h into separate hardware and generates TN(g,ƒ) and TN(h,ƒ) respectively. Since h does not host ƒ, it accesses hƒ that has one input/output access port. These ports must be connected to the host to access the actual physical ports of the shared function ƒ. g has two call sites for h (Line 8 and Line 13 in FIG. 10), with ports hƒ x0/hf y0 and hƒ x1/hf y1 respectively. When the first (second) call site is active, arguments/results to hƒ must be routed to/from the first (second) set of ports. Furthermore, the use-resource sequence for hƒ must be routed to the appropriate use-resource token stream (T3 or T4).

Hence, the datapath required to connect the ports of hƒ to the ports for each call site include: a delivery circuit DEL0(g,h) for routing the arguments for ƒ from hƒ; a delivery circuit DEL1(g,h) for routing the use-resource token stream to T3/T4; and a collection circuit COL(g,h) to route the result from f to the port for hƒ. This is shown in FIGS. 12A-C.

### 4) Control for Incremental Linking:

The newly introduced datapath blocks from Section IV-B1 require control inputs. The missing control tokens are illustrated in FIG. 13A. Since the datapath blocks are DEL0(g,h) and COL(g,h), it is natural to use dp_{gh}, the output generated by TN(g,h) to control them. Unfortunately, this is not correct, because this does not account for the possibility of repeated (or zero) calls to ƒ from h for a particular invocation.

Information about the number of times ƒ is called from h is available via the use-resource sequence generated by TN(h,ƒ). This sequence can be used to repeat the value dp_{gh} the appropriate number of times.

Consider the example in FIG. 10 where h is called twice (Line 8 and Line 13) inside g (marked as h⁰ and h¹ respectively). As a result, TN(g,h) will generate dp_{gh} twice, one for h⁰ (marked as dp⁰_{gh}) and one for h¹ (marked as dp¹_{gh}). During the invocation of h⁰, suppose ƒ is invoked twice inside h, then hƒ _x0 (from DEL0(g,h)), hƒ _y0 (for COL(g,h)) and t_{hƒ} (for DEL1(g,h)) are all generated twice while there is only one control token dp⁰_{gh}; this token must be repeated in the appropriate manner to avoid deadlock. A similar issue arises for the invocation of h¹ when ƒ inside h is invoked either more than once or zero times during h¹.

FIG. 13B shows the Control Path design for the hierarchical linker. The CP (g,h,f) is the Control Path for the nested case when g calls h and h calls ƒ. It has two inputs: dp_{gh} and t_{hƒ}, and generates two output control tokens: dp_{ghƒ} for the datapath token transfer (i.e., for DEL0(g,h) and COL(g,h)) and t_{ghƒ} for the control token transfer (i.e., for DEL1(g,h)). The behavior of this component is the following:
CP (g,h,ƒ) receives the data token dp_{gh} indicating which call site for h is next. It also receives the use-resource
If the use-resource sequence indicates N invocations of hƒ, the token dp_{gh} is sent N times to control the collection and delivery circuits DEL0(g,h) and COL(g,h) (labeled dp_{ghƒ} in FIG. 13B).
If the use-resource sequence indicates N invocations of hƒ, there is one additional use-resource token (since the use-resource sequence use run-length encoding to represent N); hence, the control input to DEL1(g,h) must repeat dp_{gh} (N+1) times. This token stream is labelled tghf.
   The completed dataflow graph is shown in FIG. 13B.

### C. Function Pointers

PipeLink handles regular function calls and memory access in a unified way. The basic approach can be extended to also support programs that use function pointers in certain contexts, permitting us to translate programs that previously were unsupported by dataflow HLS translations.

A function pointer can be viewed as a value that determines which access ports of a hardware function block should be accessed. In other words, a function pointer is used to route arguments/return values from/to the caller to/from different functions. This is similar to the way a pipelined asynchronous memory uses address values to route address and data to the corresponding memory bank/location. Inspired by this, PipeLink handles data pointers (accessing memories) and function pointers (accessing functions) uniformly.

FIG. 14 shows a data pointer example where ptr points to memory bank A (when c is true) and B (when c is false) conditionally. Similarly, it also shows a function pointer example where ƒ Ptr points to function ƒ (when c is true) and g (when c is false) in the same way. PipeLink treats the memory banks and regular function blocks as equal, so these two programs have exactly the same behavior and PipeLink synthesizes the same control and data path for them.

PipeLink tracks the definition and uses of pointers in the LLVM IR to compute a set of candidate memory targets for each data pointer, and a set of candidate functions for each function pointer. It also records the conditions associated with each binding. Each candidate memory/function is assigned an integer index, and this index is used to route data to/from the actual memory/function. Sharing of the memory/function is handled by the unified scheme outlined earlier.

With this approach, C++ programs can be handled with virtual function dispatch, a program topology that is normally not supported by mainstream HLS tools.

### D. Summary

PipeLink divides the circuit synthesis into a compilation stage where each function is synthesized into separate hardware modules, and a linking stage where the incremental linker generates the “glue” logic to combine the modules into a whole program dataflow graph. The separation of compilation and linking enables PipeLink to incrementally compile a new function into a circuit and generate the linking circuit for it without resynthesizing every function again.

PipeLink's design enables an HLS approach where functions are pre-synthesized into a HLS library. The final program can be generated relatively quickly by reusing pre-synthesized logic combined with incremental linking.

### V. Modular Dataflow Optimization

PipeLink converts a program into a static dataflow graph using a set of standard building blocks: token source, token sink, n-way copy, two-input controlled merge (MERGE), two-input controlled split (SPLIT), n-input function (FUNC), and an initial token buffer. These components can be translated directly into either synchronous elastic circuits or asynchronous circuits; in this Example the asynchronous circuit path is taken. In either case, the complexity of the final implementation is directly related to the structure of the dataflow graph and the complexity of individual components. Several dataflow graph optimizations are performed to improve the quality of the final implementation.

### A. Basic Clustering

PipeLink is built on top of the LLVM compiler infrastructure, and hence operates on the LLVM IR. LLVM encodes expressions into three-address IR instructions, and the HLS engine maps each of them into individual FUNC operators resulting in a large number of such function units. Like many previous papers, PipeLink clusters FUNC operators within a single basic block into a larger monolithic FUNC operator. This reduces the latching overhead and permits logic optimization across operators within a single basic block. The potential cost of this optimization is a throughput penalty, but experience with standard benchmarks shows that this transformation does not introduce new bottlenecks.

A second clustering operation (also supported by previous tools) that is supported is to identify opportunities for grouping a sequence of 2-way MERGE blocks into an n-way MERGE. This transformation also requires computing a new control token for the n-way MERGE. This transformation is called MERGE flattening, as it “flattens” a tree of 2-way MERGE blocks. A similar clustering operation is used for flattening 2-way SPLIT blocks. These two transformations are helpful for nested conditionals in a program, switch statements, and for optimizing the logic generated by the incremental linker.

### B. Split/Merge Fusion

Consider a program that sets y to g(x) if a condition c is true, and to ƒ(x) if the condition is false. If this is written using an if-statement, then the dataflow graph generated is shown in FIG. 15. This has the benefit that only one of ƒ or g is evaluated, saving energy; however, if the two functions are very simple, then the extra overhead introduced by latches and dataflow control might outweight the benefits of conditional execution. In the latter case, this sub-graph can be replaced with a single FUNC module that implements the C expression “c? g (x):ƒ(x)”; this is called split/merge fusion.

To support this optimization, PipeLink identifies all tokens that are generated under the same control-flow condition. This can be done by dataflow graph analysis as follows: (a) for any dataflow FUNC module, all inputs and outputs are generated under the same control-flow condition; (b) the control input token to a SPLIT has the same control-flow condition as its data input; (c) the control input token to a MERGE has the same control-flow condition as its data output. Finally, the control flow conditions of the two data outputs of a split correspond to the control flow condition of the data input combined augmented with either true or false based on the control token input value (similarly for the merge). Hence, a fusion opportunity is identified by the fact that the split and merge pair have the same control input, and their data outputs and inputs match.

### C. Cross Basic-Block Clustering

Once control flow conditions are identified as described above, PipeLink can also cluster FUNC modules across basic block boundaries. For example, consider a program fragment of the form

$$x = a + b * c ;$$

$$if ( c > 0 ) \{ z = 1 \}$$

$$y = b * c ;$$

In this case, the assignments to variables x and y are generated under the same control-flow condition. PipeLink can cluster such FUNC elements together. While this preserves data-dependencies, there is one additional constraint that must be introduced for this particular cross-basic block clustering step. To understand why, consider the following modified example:

$$x = a + b * c ;$$

$$if ( c > 0 ) \{ z = 1 + x \}$$

$$y = b * c + z ;$$

In this particular example, there is a potential clustering opportunity that groups the first and third assignments together. However, clustering also introduces a new synchronization point in the computation—in particular, a FUNC block receives all input tokens before producing all output tokens. This is acceptable for the earlier example, but not for the program above because there is a data-dependence between x (an output of the potential cluster) and z (an input to the potential cluster). This would result in deadlock. To avoid this problem, paths through the dataflow graph from potential cluster outputs to cluster inputs are checked for, and the cluster is partitioned to ensure that output to input dependencies are eliminated.

Finally, such output to input dependencies can also be introduced through function calls or memory access. To support modular optimization, a function specifies ordering constraints for its input and output ports: an ordering constraint between two ports means that there is a potential data-dependency from an input to an output. These ordering constraints are used to augment the cluster partitioning algorithm so that the cross basic-block clustering step can safely be applied without requiring whole program dataflow graph analysis.

### VI. Evaluation

PipeLink was implemented using the LLVM compiler framework. LLVM's clang was used to compile C programs 1.00 into LLVM IR and optimize the IR using existing LLVM passes. Next, the ACTN (Section III) was implemented as LLVM passes. These passes accept optimized LLVM IR as input and generate dataflow circuit graphs as their output.

A standalone dataflow graph optimizer was developed in C++, which takes in the generated dataflow graph from the HLS engine described herein, applies dataflow optimizations (Section V), and emits the optimized dataflow graph. Finally, the asynchronous circuit back-end developed by Rui et al. (Rui Li, Lincoln Berkley, Yihang Yang, and Rajit Manohar. Fluid: An asynchronous high-level synthesis tool for complex program structures. In 27th International Symposium on Advanced Research in Asynchronous Circuits and Systems (ASYNC 2021), 2021) is built upon to map the optimized dataflow graphs into asynchronous circuits in a 28 nm technology.

TABLE I
PipeLink Analysis

| | # of elements | # of elements | Merge/Split |
|---|---|---|---|
| Benchmark | (before clustering) | (after clustering) | Area (%)) |
| dfmul | 1308 | 798 | 39.34 |
| dfdiv | 1818 | 1148 | 41.92 |
| sha | 1713 | 879 | 21.33 |
| adpcm | 7189 | 3065 | 26.18 |
| diff | 41 | 23 | 5.80 |
| fft | 898 | 494 | 24.77 |
| fir | 203 | 109 | 19.79 |
| geometric mean | 1013 | 539 | 24 |
| dfmul | 1308 | 798 | 39.34 |
| dfdiv | 1818 | 1148 | 41.92 |
| sha | 1713 | 879 | 21.33 |
| adpcm | 7189 | 3065 | 26.18 |
| diff | 41 | 23 | 5.80 |
| fft | 898 | 494 | 24.77 |
| fir | 203 | 109 | 19.79 |
| geometric mean | 1013 | 539 | 24 |

### A. Setup

Circuit synthesis. Each dataflow graph component is translated into a unique pipeline stage, and the data transfers between pipelined stages use the bundled data protocol (Carver Mead and Lynn Conway. Introduction to VLSI systems. Addison-Wesley, 1980). The control for each pipelined stage uses micro-pipelines (Ivan E. Sutherland. Micropipelines. Communications of the ACM, 1989). The control circuits (one per dataflow operator type) are custom designed asynchronous logic, and the bundled-data datapath uses combinational logic for computation that is mapped to a standard cell library.

Simulation methodology. A discrete-event simulator was built to simulate the synthesized bundled data circuits with 4-phase handshake for process communication. To annotate the simulator, HSPICE was used to extract the control circuit performance metrics in a 28 nm process technology. For the combinational logic, a commercial logic synthesis tool with a commercial 28 nm standard cell library was used to determine delay/power/area. Synchronous results were obtained using the same cell library and logic synthesis tool.

Workloads. Four applications (dfmul, dfdiv, sha, adpcm) from an HLS benchmark suite (Chstone; Yuko Hara, Hiroyuki Tomiyama, Shinya Honda, Hiroaki Takada, and Katsuya Ishii. Chstone: A benchmark program suite for practical c-based high-level synthesis. In International Symposium on Circuits and Systems (ISCAS 2008), 18-21 May 2008, Sheraton Seattle Hotel, Seattle, Washington, USA, pages 1192-1195. IEEE, 2008) were used. In addition, three widely used benchmarks were selected: a differential equation solver (differential) from (P. G. Paulin and J. P. Knight. Force-directed scheduling for the behavioral synthesis of asics. IEEE Transactions on Computer-Aided Design of Integrated Circuits and Systems, 8(6): 661-679, 1989), and ƒƒt and βr from (Andrew Canis, Jongsok Choi, Mark Aldham, Victor Zhang, Ahmed Kammoona, Jason Helge Anderson, Stephen Dean Brown, and Tomasz S. Czajkowski. Legup: high-level synthesis for fpga-based processor/accelerator systems. In John Wawrzynek and Katherine Compton, editors, Proceedings of the ACM/SIGDA 19th International Symposium on Field Programmable Gate Arrays, FPGA 2011, Monterey, California, USA, February 27, Mar. 1, 2011, pages 33-36. ACM, 2011).

Comparison. The presently described tool was compared against an academic HLS tool LegUp v4.0 (Andrew Canis, Jongsok Choi, Mark Aldham, Victor Zhang, Ahmed Kammoona, Jason Helge Anderson, Stephen Dean Brown, and Tomasz S. Czajkowski. Legup: high-level synthesis for fpga-based processor/accelerator systems. In John Wawrzynek and Katherine Compton, editors, Proceedings of the ACM/SIGDA 19th International Symposium on Field Programmable Gate Arrays, FPGA 2011, Monterey, California, USA, February 27, Mar. 1, 2011, pages 33-36. ACM, 2011) as well as two commercial HLS tools Commercial 1 and Commercial 2.

Metrics. Delay (ps), Area (μm²), Energy (pJ) and Throughput (MHz) were measured. Leakage power results are not shown, as they are always proportional to the area. Each benchmark was run twenty times (the input data are provided by each benchmark, and there are dozens of them to cover different cases) and averages across the runs were used to report benchmark statistics. The same methodology was used to collect results for both PipeLink and other HLS tools.

### B. Experiment Results

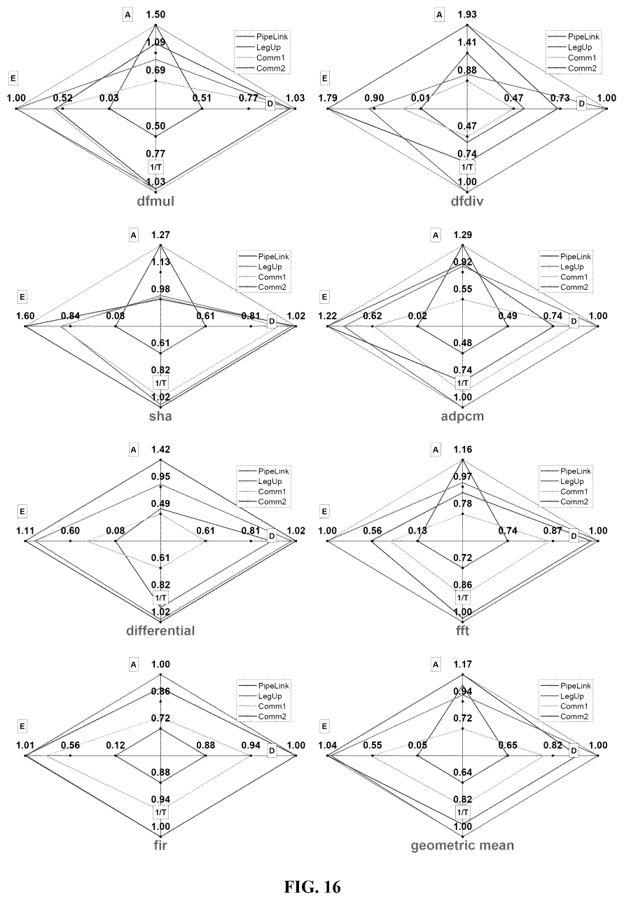

Comparison. Table I shows the detailed analysis of PipeLink. It synthesizes approximately 1000 dataflow elements (FIG. 1) for these benchmarks, and can reduce the number by half through operator clustering and Split/Merge fusion (Section V). Table II shows the normalized performance numbers of PipeLink, Commercial 1 and Commercial 2 compared to Legup. FIG. 16 shows per-benchmark spider plots of normalized performance (relative to Legup) as well as the geometric mean of the normalized performance across all HLS benchmarks. Note that the inverse of the normalized throughput is plotted; hence, for all metrics, lower is better. These spider plots can better illustrate the trade-off among Delay, Area, Energy and Throughput.

TABLE II
Normalized Performance (compared to Legup)

| | PipeLink | | | | Commercial 1 | | | | Commercial 2 | | | |
|---|---|---|---|---|---|---|---|---|---|---|---|---|
| Benchmark | Delay | Area | Energy | Throu. | Delay | Area | Energy | Throu. | Delay | Area | Energy | Throu. |
| dfmul | 0.51 | 1.50 | 0.04 | 1.99 | 1.03 | 0.69 | 0.70 | 0.97 | 1.00 | 1.23 | 0.66 | 1.00 |
| dfdiv | 0.53 | 1.40 | 0.01 | 1.89 | 0.47 | 0.88 | 0.39 | 2.11 | 0.72 | 1.93 | 1.67 | 1.39 |
| sha | 0.61 | 1.27 | 0.10 | 1.63 | 0.94 | 0.99 | 1.08 | 1.06 | 1.02 | 0.98 | 1.18 | 0.98 |
| adpcm | 0.49 | 1.29 | 0.02 | 2.08 | 0.86 | 0.55 | 0.82 | 1.17 | 0.75 | 1.04 | 1.16 | 1.33 |
| diff | 0.91 | 0.58 | 0.08 | 1.10 | 0.61 | 0.49 | 0.41 | 1.64 | 1.02 | 1.42 | 1.11 | 0.98 |
| fft | 0.74 | 1.16 | 0.11 | 1.39 | 0.86 | 0.78 | 0.63 | 1.16 | 0.98 | 0.93 | 0.79 | 1.02 |
| fir | 0.88 | 0.72 | 0.15 | 1.13 | 0.94 | 0.78 | 0.90 | 1.06 | 1.00 | 0.93 | 1.01 | 1.00 |
| geomean | 0.65 | 1.08 | 0.05 | 1.56 | 0.79 | 0.72 | 0.56 | 1.26 | 0.92 | 1.17 | 1.04 | 1.09 |

PipeLink consistently has the best energy per benchmark. Compared with Legup, the minimum energy saving is 6.67× for fir, the maximum saving is 100× for dfdiv and the average saving is 20×. Even compare with Commercial 1, PipeLink still saves energy by 12× on average. PipeLink synthesizes asynchronous circuits and only triggers the processes with input data tokens, which results in significant energy savings.

In most cases, PipeLink has the smallest delay (0.62× on average) and the highest throughput (1.64× on average). The improvement comes from two aspects: (i) PipeLink does extensive operator clustering, which results in lower latency circuits through logic optimization and specialization; (ii) when there are (nested-) if statements, the delay/throughput of asynchronous circuits depends on the activated processes at run-time while synchronous circuits are limited by the worse-case scenario. For differential benchmark, however, Commercial 1 (0.61χ) is much faster than PipeLink (0.91χ). This is because differential primarily consists of a loop. PipeLink has to synthesize multiple MERGEs and SPLIT s for loop control (Rui Li,

Lincoln Berkley, Yihang Yang, and Rajit Manohar. Fluid: An asynchronous high-level synthesis tool for complex program structures. In 27th International Symposium on Advanced Research in Asynchronous Circuits and Systems (ASYNC 2021), 2021; John Teifel and Rajit Manohar. Static tokens: Using dataflow to automate concurrent pipeline synthesis. In 10th International Symposium on Advanced Research in Asynchronous Circuits and Systems (ASYNC 2004), 19-23 April 2004, Crete, Greece, pages 17-27. IEEE Computer Society, 2004), and they increase the total delay and lower the throughput.

PipeLink increases the area by 1.61× on average. The penalty can be attributed to the synthesis of MERGEs and SPLIT s for if and loop statements that remain unfused, and the collection and delivery circuits for accessing shared resources. Table I shows that the area of MERGEs and SPLIT s takes up amost 25% of the total circuit area on average. In addition, PipeLink does not currently include an operator scheduling phase, and hence datapath operators that might be shared by commercial HLS tools would be replicated in PipeLink.

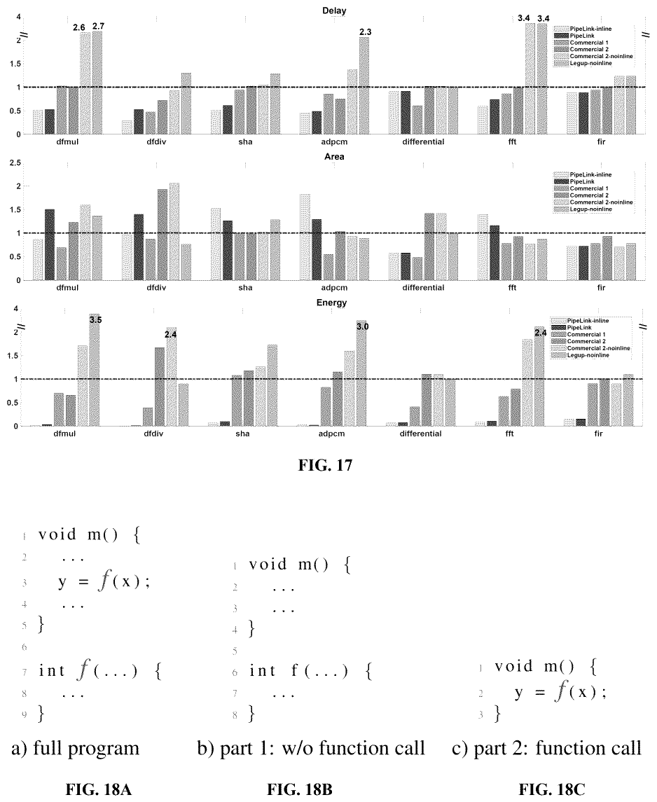

Inline vs non-inline: By default, PipeLink does not inline functions (unless specified in the program) while other tools try to inline functions. In order to study the effect of inlining, the benchmarks were also run with PipeLink-inline, Commercial2-noinline and Legup-noinline. The inlining behavior of Commercial 1 was not able to be changed. FIG. 17 shows the normalized performance compared to Legup (the blue dash line). Note that differential and fir only contain one function call, so inlining has minimal effect on these two benchmarks. Inlining decreases the delay for all tools. For PipeLink, inlining has varying effects on area and energy (the numbers increase for some benchmarks and decrease for others). For PipeLink, inlining means more redundant operators are synthesized, but it also has more opportunities for clustering. Also, inlining eliminates the resource sharing logic.

Other tools, however, do not share resources at function (i.e., hardware module) boundaries, so disabling inlining results in the creation of many additional hardware modules. These modules are instantiated at multiple places by their callers. This results in a significant increase in both area and energy when inlining is disabled.

### VII. Related Work

Dataflow HLS. Some synchronous HLS tools generate elastic dataflow circuits (e.g., Lana Josipovic, Andrea Guerrieri, and Paolo Ienne. Invited tutorial: Dynamatic: From C/C++ to dynamically scheduled circuits. In Stephen Neuendorffer and Lesley Shannon, editors, FPGA '20: The 2020 ACM/SIGDA International Symposium on Field-Programmable Gate Arrays, Seaside, CA, USA, Feb. 23-25, 2020, pages 1-10. ACM, 2020; Lana Josipovic, Andrea Guerrieri, and Paolo Ienne. Synthesizing general-purpose code into dynamically scheduled circuits. IEEE Circuits and Systems Magazine, 21(2): 97-118, 2021; Richard Townsend, Martha A. Kim, and Stephen A. Edwards. From functional programs to pipelined dataflow circuits. In Proceedings of the 26th International Conference on Compiler Construction, CC 2017, page 76-86, New York, NY, USA, 2017. Association for Computing Machinery). Lana et al. have done a series of works on mapping C/C++ programs into synchronous dataflow circuits. DynSchedule, GeneralCodeSynthesis, and CToDataflow use the distributed token network design for pipelined memory access, but the circuit pipelining could be harmed as described in Section II-C2. Furthermore, they rely on customized out-of-order load-store queue (Lana Josipovic, Philip Brisk, and Paolo Ienne. An out-of-order load-store queue for spatial computing. ACM Trans. Embed. Comput. Syst., 16(5s): 125:1-125:19, 2017) for pipelined memory accesses within the activated basic block in program's control flow graph, which could potentially incur high overhead. Lastly, there is not much descriptions about how they support general-purpose function calls in a pipelined manner. PipeLink however, unifies the pipelined function calls and pipelined memory accesses, and proposes an adaptive control token network design to improve circuit pipelining over distributed token network design.

FunctionSynthesis synthesizes functional programs into pipelined dataflow circuits. In functional programming, each function is “stateless” and does not have the side-effects as mentioned in Section II-B, so their stateless functions can be shared in a pipelined manner without requiring to enforce the access order among invocations.

Some tools directly map software programs into asynchronous dataflow circuits. Spatial computing, CASH, and Pegasus generates asynchronous circuits which are based on the MicroPipelines design, and they only support blocking function calls. AutoCtrl generates distributed asynchronous control circuits automatically in a hierarchical and systematic manner. It “simulates” the program counter in asynchronous control circuits and only supports blocking function calls.

Asynchronous synthesis. Balsa is based on syntax-directed translation to map message-passing hardware description language (HDL) into an asynchronous circuit, and it only allows sequential function calls. BehaviorSynthesis presents a method for behavioral synthesis of asynchronous circuits, and the datapath and control architecture is expressed in Balsa-language, so it also only supports sequential function calls. STF and DataDecomposition maps high-level circuit description programs into concurrent hardware modules. They support pipelined function calls with restricted patterns, e.g., function can be called at most once within each loop iteration.

Static HLS. Most commercial tools are static HLS tools, and they will do function inlining by default when doing the synthesis. They also provide directives and pragmas for users to explicitly specify function pipelining. However, as mentioned in Section II-C3, pipelined resource sharing in statically-scheduled circuits could be heavy as it needs to unroll the loops and inline sub-functions, so users need to be very careful before deciding to pipeline a function. The academia HLS tools also share similar problems.

Dataflow machines There are a lot of works in dataflow machines. They use software compilers to generate dataflow instructions which are later executed on the machines in a dataflow manner. This work, however, is a high-level synthesis tool which focuses on synthesizing dataflow ASICs (including pipelined resource sharing system) from C/C++ programs, so this work is orthogonal to them.

### VIII. Conclusion

Described herein is PipeLink, a dataflow HLS engine to map programs into asynchronous dataflow circuits. It has a generic pipelined resource sharing mechanism, and support pipelined memory access and function calls uniformly. It supports function pointer, which could not be handled even by some of the commercial tools. PipeLink also applies a range of dataflow optimizations to improve the circuit performance. Results show that PipeLink can dramatically save energy, and improve delay and throughput performance.

### Example 2-Fluid: An Asynchronous HLS Tool for Complex Program Structures

This Example presents an HLS methodology tailored to high-performance asynchronous dataflow circuits building on prior work in dataflow synthesis (John Teifel and Rajit Manohar. Static tokens: Using dataflow to automate concurrent pipeline synthesis. In 10th International Symposium on Advanced Research in Asynchronous Circuits and Systems (ASYNC 2004), 19-23 Apr. 2004, Crete, Greece, pages 17-27. IEEE Computer Society, 2004). Furthermore, a new solution to dataflow circuit generation needed when translating real-world programs with complex control flows is proposed. This approach is implements in the LLVM compiler framework, and it is shown that the generated circuits achieve better performance in throughput and energy compared to a number of existing HLS tools. The benefits of dataflow graph optimizations on the quality of the generated circuits is also quantified.

### 2.1 Introduction

There has been significant activity in translating behavioral descriptions of asynchronous computations into asynchronous circuits, and the majority of these efforts focus on translating a concurrent, message-passing programming language into asynchronous circuits (S. F. Nielsen et al. A behavioral synthesis frontend to the haste/tide design flow. In ASYNC 2009. 19, 56; J. Hansen et al. Concurrency-enhancing transformations for asynchronous behavioral specifications: A data-driven approach. In ASYNC 2008; J. Cortadella et al. Desynchronization: Synthesis of asynchronous circuits from synchronous specifications. IEEE Transactions on Computer-Aided Design of Integrated Circuits and Systems, 2006). There has also been previous work in translating software programs into asynchronous circuits (Mihai Budiu, Girish Venkataramani, Tiberiu Chelcea, and Seth Copen Goldstein. Spatial computation. In Shubu Mukherjee and Kathryn S. McKinley, editors, Proceedings of the 11th International Conference on Architectural Support for Programming Languages and Operating Systems, ASPLOS 2004, Boston, MA, USA, Oct. 7-13, 2004, pages 14-26. ACM, 2004; G. Venkataramani, M. Budiu, T. Chelcea, and S. Goldstein. C to asynchronous dataflow circuits: An end-to-end toolflow. In IWLS, 2004). Furthermore, some synchronous HLS tools also synthesize latency-insensitive dataflow circuits (Richard Townsend, Martha A. Kim, and Stephen A. Edwards. From functional programs to pipelined dataflow circuits. In Proceedings of the 26th International Conference on Compiler Construction, CC 2017, page 76-86, New York, NY, USA, 2017. Association for Computing Machinery; Lana Josipovic, Andrea Guerrieri, and Paolo Ienne. Invited tutorial: Dynamatic: From C/C++ to dynamically scheduled circuits. In Stephen Neuendorffer and Lesley Shannon, editors, FPGA '20: The 2020 ACM/SIGDA International Symposium on Field-Programmable Gate Arrays, Seaside, CA, USA, Feb. 23-25, 2020, pages 1-10. ACM, 2020; Lana Josipovic, Andrea Guerrieri, and Paolo Ienne. Synthesizing general-purpose code into dynamically scheduled circuits. IEEE Circuits and Systems Magazine, 21(2): 97-118, 2021). Other tools use domain-specific languages and special pragmas to simplify the high-level synthesis problem. The most complex aspect of generating dataflow circuits is managing conditional execution and conditional generation of tokens. Prior work either mostly avoids conditional tokens, or only supports conditional tokens for simple control structures.

This Example presents Fluid, a HLS tool that translates C programs into asynchronous dataflow circuits. This work extends existing dataflow synthesis techniques to a wider class of software programs by supporting complex control-flow structures that naturally occur in software. This also permits the use of optimizations that might create complex control structures. Optimizations that operate directly on the dataflow graph structure are also incorporated, further improving the results.

Fluid goes through a number of steps to translate C programs to asynchronous dataflow circuits. Starting from the C program, the LLVM compiler framework is used to generate the LLVM IR (Intermediate Representation). Then, LLVM would apply the optimization passes and produce the optimized IR, which is a CDFG (Control-Data Flow Graph) that captures the control and data dependencies of the original program. Fluid analyzes the IR and rewrites the CFG into canonical form to handle complex control structures. After this, Fluid synthesizes the dataflow circuit which is represented as a dataflow graph. Then, it applies several dataflow optimizations to produce an optimized dataflow graph. Then, the optimized dataflow graph is mapped to asynchronous bundled-data circuits through technology mapping. Lastly, an asynchronous circuit simulator was built to simulate the generated circuits and get the computation results and performance numbers. Fluid is compared against an academic HLS tool (LegUp) and two different commercial HLS tools on a combination of micro-benchmarks and public HLS benchmarks. The results show that Fluid can increase the circuit speed by 2×, reduce the energy consumption by 5× and increase the throughput by 2.5×.

Advancements discussed herein include: (i) an asynchronous HLS tool that translates C to an asynchronous dataflow circuit with results that are significantly superior to an academic HLS tool and outperform commercial HLS tools on throughput and energy; (ii) a new technique for dataflow graph construction in the presence of complex control flow; and (iii) a collection of dataflow graph optimizations that improve the quality of the final implementation. The remaining chapter is organized as follows: Section 2.2 introduces the prior work that is built on. Section 2.3 presents how Fluid constructs dataflow graphs based on the control-flow graph (CFG), including support for irregular CFGs (Section 2.3.5). Section 2.5 describes the dataflow optimizations currently used in Fluid. Section 2.6 evaluates Fluid against three other HLS tools.

An overview of the large body of related work is provided in Section 2.7.

### 2.2 Background

### 2.2.1 LLVM

To translate C programs, the production-quality LLVM open-source compiler framework is leveraged. The LLVM front-end translates different programming languages into a common intermediate representation (IR). LLVM also includes a large number of optimization passes that re-write and improve the quality of the IR from a software perspective.

The standard data structure used for optimizing software programs is the control flow graph (CFG). Nodes in this graph are basic blocks, which correspond to a collection of consecutive sequential statements with a single entry point and single exit point. Outgoing edges from a basic block correspond to different potential successors, with the successor chosen based on a specified condition. For-loops and while-loops result in cycles in the CFG.

### 2.2.2 Dataflow Circuit

Dataflow circuit consists of dataflow elements that communicate with their predecessors and successors through handshake protocols, thus the circuits do not require global control. Dataflow elements remain idle until they receive tokens. The circuits can be implemented with either synchronous or asynchronous logic.

In this work, the dataflow circuits are built using the eight basic dataflow elements shown in FIG. 20.
COPY. It receives one input token and duplicates it to multiple output ports. More specifically, it will not receive new input tokens until all output tokens have been acknowledged by the successors.
FUNC. It receives input tokens, computes some function (e.g., add, multiply, divide, shift, modulo, compare) of the received values, and sends the results to the output port(s).
MERGE. It receives multiple inputs from input ports and one control token c from the control port, and then sends one of the inputs to the output port based on the control token value. In this work, it is assumed that the left (right) port is selected under the false (true) condition.
SPLIT. It receives one input from the input port and one control token from the control port, and then sends it to one of the output ports based on the control token value. Similar to MERGE, it is assumed that the left (right) port is selected under the false (true) condition.
SINK. It is used to absorb the unused tokens in the circuit.
SOURCE. It generates tokens with pre-configured constant values and sends it to the output port.
BUF. It is a one-place FIFO.
INIT. It is a BUF initialized with a data token (configured during reset).

Any dataflow graph that is constructed using these elements is guaranteed to be deterministic, and has the property of slack elasticity. Slack elasticity provides a theoretical guarantee of correct behavior under a wide range of pipelining options.

### 2.2.3 Static Token Form

This work builds on previous efforts to translate hardware description languages to dataflow asynchronous circuits. In particular, the static token form (STF) representation was introduced to translate the CHP hardware description language into a dataflow graph. The CHP language was translated into a CDFG, and variables with multiple definitions (for example, the left hand side of an assignment statement) and uses (for example, the right hand side of an assignment statement) in CHP were re-written into the canonical STF form. Informally, STF guarantees that the conditions that cause a variable to be defined match the condition under which it is used; this permits variables to be replaced by channels, and values become tokens in the dataflow graph. STF combines concepts from both static single assignment (SSA) form and static single information (SSI) form into a unified analysis. If a variable is conditionally used, STF inserts a split instruction to conditionally create a new token for the conditional use; if a variable comes from multiple definitions under various conditions, STF inserts a merge instruction to conditionally select from multiple defs and assign the new token to the variable.

It is fairly straightforward to convert sequential statements into static token form. The key is to handle the if case and the loop case.

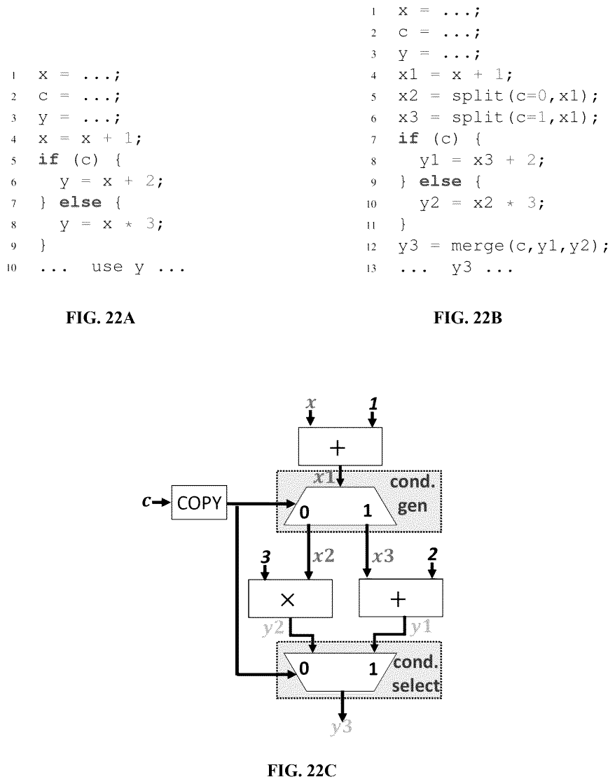

if case. FIG. 22A shows the same if statement as the one in the static HLS example of FIGS. 21A-C. x is redefined at Line 4 and a new version of x is generated. Similarly, y is also redefined at Line 6 and Line 8 respectively. To satisfy the SSA requirement, STF in FIG. 22B labels x as x1 (at Line 4) and y as y1 (at Line 8) and y2 (at Line 10). Furthermore, x1 is conditionally used in both branches, so the STF contains two split instructions to conditionally generate x2 and x3 for the uses at Line 8 and Line 10 respectively. Lastly, after the if statement, y comes from either the true branch (y1) or the false branch (y2), so STF inserts a merge instruction to conditionally select y1 and y2 based on the condition c and assign the value to y3 (not y). FIG. 22C shows the synthesized circuit for the iƒ example. The SPLIT operator conditionally generates token x2 and x3 from x1, and the MERGE operator conditionally selects from y1 and y2 and assigns the new token to y3.

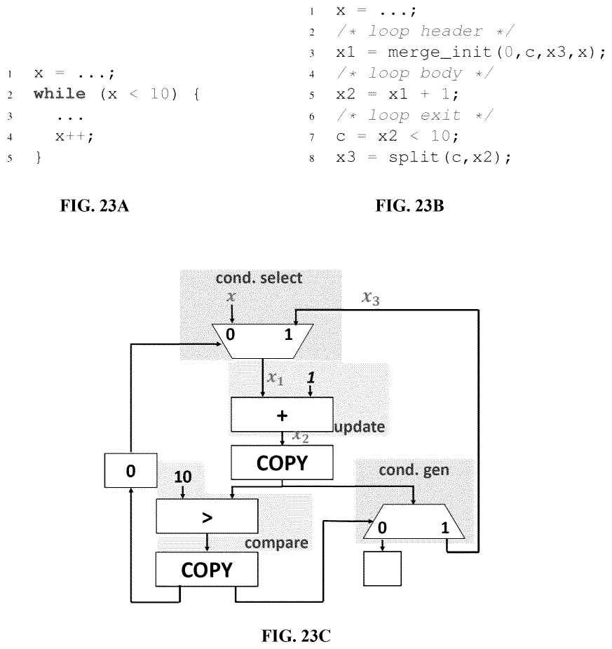

loop case. FIG. 23A shows the loop statement, which runs the loop until the loop counter x is greater or equal than 10. The loop condition “x<10” (Line 2) uses variable x that comes from two definitions: initial x (Line 1) before entering the loop, and updated x (Line 4) during the execution of the loop. Therefore, in FIG. 23B, the STF contains a merge instruction (Line 3) to conditionally select x in the loop header block. Then in the loop body block, a new loop counter x2 is generated. In the loop exit block, loop condition c is updated based on the value of x2, and a new version of counter x3 is conditionally generated if the loop continues (i.e., c is true).

The challenge comes from the loop condition c that is used in the merge instruction (Line 3), because it is used (Line 3) before being generated (Line 7). During the initial execution of the loop, the merge instruction requires a control token that is generated from its output, and this is a dependency deadlock. To break the deadlock, the STF attaches an init instruction (with initial value 0) coupled with the merge instruction, so the merge instruction has an initial control token 0 before the loop starts. As a result, the merge instruction would select the initial x before entering the loop. The final circuit is shown in FIG. 23C. When the loop finishes, the loop condition “x<10” becomes 0, which is stored in the INIT operator. In this case, the circuit restores to the initial state and is ready for the next run.

STF does no optimizations to the synthesized dataflow circuits, and it only deals with CHP programs with simple control structures.

### 2.3 Fluid Design

Fluid is written as a compiler pass within the LLVM framework. It takes an optimized IR as input, and re-constructs the CFG for the program. While LLVM optimization passes improve the quality of the IR, they can re-structure the CFG. To convert this optimized CFG to static token form, new techniques discussed below are introduced that modify the CFG and IR so that the resulting program is equivalent to the original IR, and can be readily converted into static token form. Finally, dataflow circuit optimizations is applied to obtain the final circuit.

IR constructs that perform computation (e.g. addition, division, etc.) can be translated into dataflow function blocks in the usual manner. The challenging part of STF generation is creating the SPLIT and MERGE circuits correctly, along with their control flow conditions. This aspect is focused on below.

As discussed above, STF requires that a variable definition (a “def”) and use occur under the same condition. After the CFG is constructed using standard techniques, Fluid computes the def-condition and use-condition for each variable in the program. If the def-condition and the use-condition for a variable are different, Fluid constructs a delivery circuit to create a conditional copy of the variable; symmetrically, it constructs a collection circuit that conditionally selects the correct version of the variable from multiple conditional definitions of the variable. This process is detailed below.

This analysis makes extensive use of the standard compiler notion of dominators. A basic block A dominates B if every control flow path from entry to B must pass through
A. A basic block B post-dominates A if every path from A to the exit must pass through
B. The immediate dominator for a basic block is its closest dominator (apart from itself) in the control flow graph.

### 2.3.1 Canonical Form

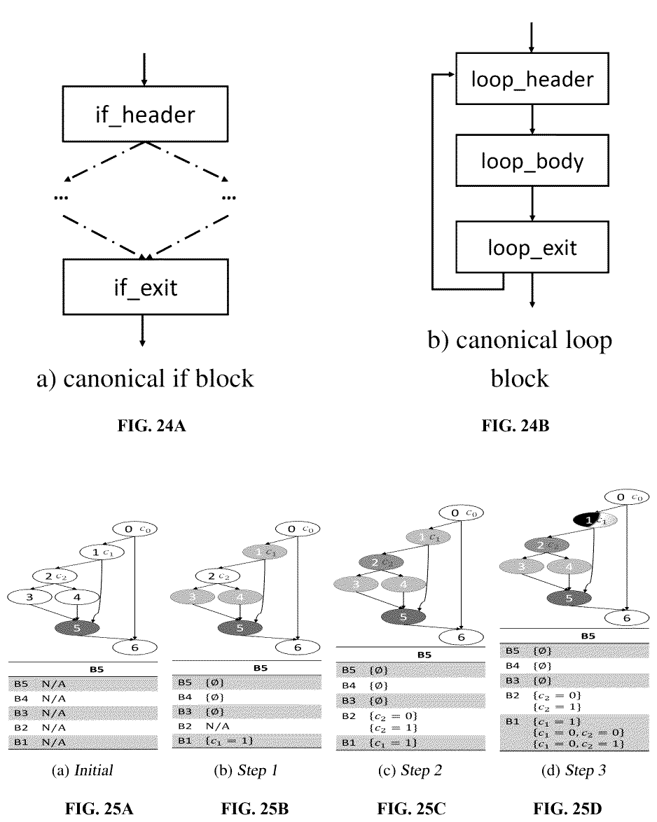

To simplify the design of Fluid, a canonical form requirement is imposed on CFGs which consists of two parts:
every loop has a single-entry and single-exit point;
every if-block is properly-nested;
   The first constraint means that each loop could be treated as one super block which is single-in-single-out as shown in FIG. 24A. The second constraint means that each if could be treated as a single-in-single-out super block as shown in FIG. 24B. Note that each block (loop_header, loop_body, loop_exit, if_header, if_exit) itself could be another if or loop block, which also satisfies the canonical form.

Section 2.3.5 provides techniques to handle a commonly occurring class of non-canonical CFGs. The loop constraint means all loop-carried dependencies (back edges) can be handled using the technique in, and those edges in the CFG for condition extraction below can be ignored.

### 2.3.2 Condition Extraction

Fluid is built upon Static Token Form, which needs to compute the def/use conditions of each variable. These conditions are the same as the entering conditions of the basic block where the variable lives in. Therefore, given a CFG, Fluid first extracts the conditions into each basic block from other basic blocks. Since the canonical CFG has single-entry/single-exit loops, the entire CFG can safely be divided into smaller regions: inside each small region (corresponding to a if-block or a loop-block), it has one enter (exit) block that dominates (post-dominates) all the internal blocks.

Given a block, Fluid uses reverse breadth-first-search along its predecessors to explore all the paths into this block. The search stops when it encounters the immediate dominator of this block. Furthermore, if the search encounters a loop, it will treat the whole loop block as one super block and directly skip it (i.e., without going inside the loop block).

if condition extraction. FIG. 25A shows a CFG for a iƒ example. This CFG can be divided into two smaller regions: {B₁,B₂,B₃,B₄,B₅} and {B₀,B₁,B₂,B₃,B₄,B₅,B₆}. A block can belong to multiple regions, and Fluid assigns it to the smallest region. Note that {B₃,B₄,B₅} is not considered as an independent region, because B₂ does not dominate B₅. The CFG has three branching variables c₀, c₁ and c₂ in B₀, B₁ and B₂ respectively.

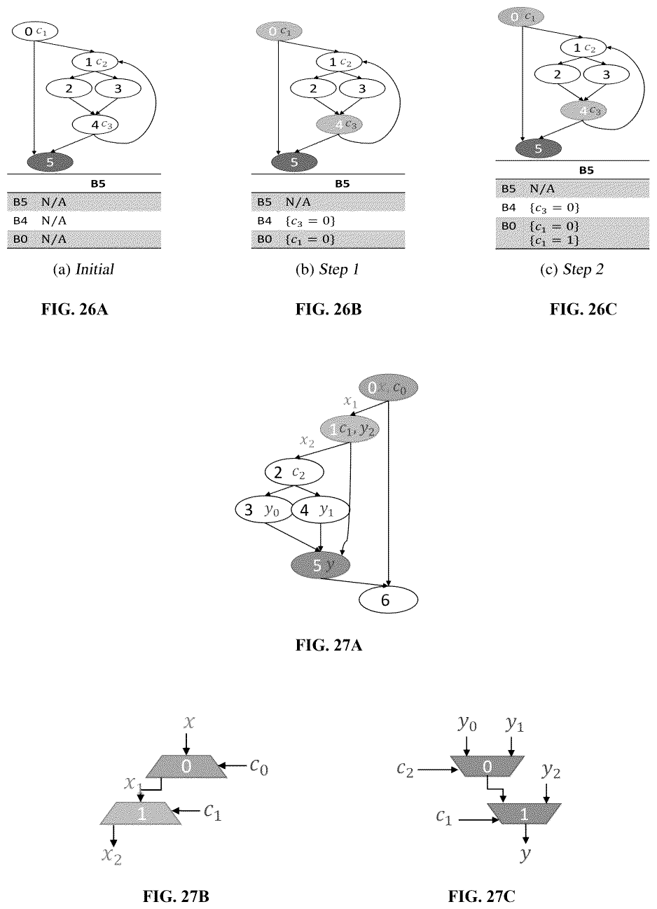

Consider B₅ as the target block. In the first step (FIG. 25B), Fluid explores the direct predecessors of B₅: {B₁,B₃,B₄}. The conditions for B₃→B₅ and B₄→B₅ are both empty, and B₁→B₅ is {c₁=1}. In the second step (FIG. 25C), Fluid further explores {B₃,B₄}'s predecessor B₂. Note that B₁ is the immediate dominator of B₅, so the search stops at B₁. Now Fluid records the conditions for B₂→B₅: {c₂=0}, {c₂=1}. In the third step (FIG. 25D), Fluid explores B₂'s predecessor B₁, and updates the conditions for B₁→B₅ to be: {c₁=1}, {c₁=0,c₂=0} and {c₁=0,c₂=1}. loop condition extraction. FIG. 26A shows a CFG for a loop example. This CFG consists of two smaller regions: {B₁,B₂,B₃,B₄} as a loop super block, and {B₀,B₁,B₂,B₃,B₄,B₅}. The loop entering condition is c₁=1, and the loop super block has a nested if-block controlled by c₂. The loop exit condition is c₃=0.

Consider B₅ as the target block. In the first step (FIG. 26B), Fluid explores the direct predecessors B₀ and B₄, and update the conditions for B₀→B₅ and B₄→B₅ respectively. In the second step (FIG. 26C), Fluid tries to further explore {B₀,B₄}'s predecessors. Since B₀ is the immediate dominator of B₅, the search stops at B₀. As for B₄, it belongs to a loop super block which is abstracted as single-in-single-out super block, so Fluid would consider B₀ (not B₂ or B₃) as B₄'s predecessor, and the condition for B₀→B₄→B₅ is {c₁=1}. Note that if the loop super block is in the middle of the search path, then the loop condition (c₃) does not appear in the condition chain; however, if the loop exit block (B₄) is the source node of the search path (e.g., B₄→B₅), then the loop condition should be kept in the condition chain. It is assumed that the source program does not have a dead loop. However, if a dead loop is present, then Fluid can be extended to handle this case by always including the loop condition in the condition chain when the loop super block appears in the search path

The merging operation. A CFG can have multiple paths between two basic blocks, each corresponding to a chain of conditions. However, two condition chains can be merged if they only have one different condition, and the two different conditions are complementary. In if-statements and loops, there is two-way branching so this is naturally satisfied. For this discussion it is assumed that multi-way branches like those from switch statements are transformed into two-way branches. However, the extension to multi-way branches is straightforward. FIGS. 25A-D have two condition chains from B₂ to B₅: {c₂=0} along B₂→B₃→B₅, and {c₂=1} along B₂→B₄→B₅. c₂ is complementary in the two chains, so the merged chain has condition { }, and the two paths treating it can be collapsed as a single virtual path B₂→B₅. This merge operation is repeatedly applied until no paths can be merged.
Theorem 1. In a canonical CFG, if there are multiple merged paths for src→dst, then dst cannot post-dominate src.
Proof. For loop-free segments of the CFG, the result is proven by contradiction. Suppose dst post-dominates src. Any path from src that adds conditions of the form cᵢ=0 or cᵢ=1 must also have a branch that includes the other condition, and they must all re-converge prior to/at dst since dst post-dominates src. Hence, all possible conditions associated with paths from src to dst exist, and they can be merged into one path src→dst. This contradicts the multi-path assumption presented herein, so dst cannot post-dominate src.

If src and dst are within the same loop, the argument above can be repeated for the sub-CFG that only includes the loop body. Otherwise suppose src belongs to Loop₁ and dst belongs to Loop₂. Since all loops are single-entry-single-exit, src→dst is divided into src→Loop1ₑₓᵢₜ→Loop2_{entry}→dst, and the argument is repeated for each segment. The case when only one of src/dst belonging to a loop is similar.
Lemma 2. If dst unconditionally connects to dst₂, then the number of merged paths for src→dst equals that for src→dst₂.
Proof. Since dst connects to dst₂ unconditionally, dst is the immediate dominator of dst₂. src→dst₂ can be divided into src→dst and dst→dst₂. The condition for dst→dst₂ is { }, so the conditions and the number of merged paths for src→dst₂ match that for src→dst.

The main result that is the basis for generating static token form is the following: Theorem 3. Given two basic blocks src and dst in a canonical CFG, there is at most one merged path from src to dst.
Proof. If dst is not reachable from src, then there is no path between them and the proof is done. If dst has one predecessor, then the CFG is traversed backward until a basic block with multiple predecessors is reached, or src is reached. If src is reached, the result trivially holds. Otherwise, call the new basic block dst^{l}. By Lemma 2, the merged path count from src to dst matches src to dst^{l}.

dst^{l} has more than one direct predecessor and is reachable from src. Suppose its immediate dominator is iDom. By the canonical form assumption, dst^{l} post-dominates iDom. Also, any path from the program entry that contains src and dst^{l} must include iDom. If that path has iDom before src, then iDom must also dominate src; otherwise a path would have been found from program entry to src to dst^{l} without iDom-a contradiction. Hence, there are two cases:
Case 1: iDom dominates src, then dst post-dominates src as well. According to Theorem 1, there exists only one merged path for (src, dst^{l}), and the proof is done.
Case 2: iDom does not dominate src, in which case iDom must be on any path from src to dst^{l}; src→dst is divided into two parts: src→iDom and iDom→dst^{l}. There is one merged path for iDom→dst^{l}, so src→dst is truncated to src→iDom. By repeating this, Case 2 is eventually reduced to Case 1.

### 2.3.3 Delivery and Collection Circuit Construction

If a token is defined in src block and used in dst block, Fluid will construct the delivery circuit to conditionally propagate this token.

Calculating the delivery conditions. In Section 2.3.2, Fluid records nestedConds, which contain the entering conditions into dst from its predecessors that are dominated by its immediate dominator iDom. Next, Fluid needs to calculate the delivery conditions for src→dst. The algorithm is shown in Algorithm 1.

Algorithm 1: getDeliveryConds(src, dst, nestedConds)

input : src, dst, nestedConds
output: deliveryConds
if nestedConds.find(src, dst) then
| return nestedConds.get(src, dst);
end
extract dst block's immediate dominator, iDom;
conditions = nestedConds.get(iDom, dst);
return getDeliveryConds(src, iDom, nestedConds).append(conditions);

If src→dst can be found in nestedConds, Fluid can directly get the delivery conditions from it. Otherwise, Fluid calculate the immediate dominator iDom of dst, divide src→dst into src→iDom and iDom→dst. The conditions for iDom→dst is known in nestedConds, so the conditions for src→iDom just needs to be calculated by applying the same rule iteratively. Based on Theorem 3, there exists only one condition chain for any src→dst, so these conditions can simply be appended together to form the final conditions.

Synthesizing the delivery circuit. Fluid synthesizes SPLIT s for each unique condition variable in the delivery conditions and connects them following the same order.

FIG. 27A shows the same CFG as in FIG. 25A. x is defined in B₀ and used in B₂, and the delivery condition for B₀→B₂ is {c₀=0,c₁=0}. In FIG. 27B Fluid synthesizes SPLIT₀ (in B₀) to generate x₁ for B₁ when {c₀=0}, and SPLIT1 (in B₁) to generate x₂ for B₂ when {c₁=0}.

Synthesizing the collection circuit. If token y in dst has multiple reaching definitions y₁, y₂, . . . , yₙ in dst's n predecessors, Fluid synthesizes the collection circuit to pick the right token. Suppose dst's immediate dominator is iDom. Starting from iDom, the program will traverse through different paths into dst's predecessors before entering into dst. The conditions associated with each traversal are the collection conditions for the corresponding predecessor. Then, Fluid synthesizes MERGEs for each unique condition variable in the collection conditions and connects them in the reverse order of the collection conditions.

In FIG. 27A B₅ receives {y₀, y₁, y₂} from {B₃,B₄,B₁}, and assigns the final value to y. The collection conditions are:

$$B 3 \to {B}_{5} : \{ {c}_{1} = 0 , {c}_{2} = 0 \} B 4 \to {B}_{5} : \{ {c}_{1} = 0 , {c}_{2} = 1 \} B 1 \to {B}_{5} : \{ {c}_{1} = 1 \}$$

FIG. 27C shows the synthesized MERGE tree in B₅.

### 2.3.4 Control Token Generation

The delivery and collection circuits consist of MERGEs and SPLIT s that require the control tokens, which could also need delivery/collection circuits if used/defined conditionally.

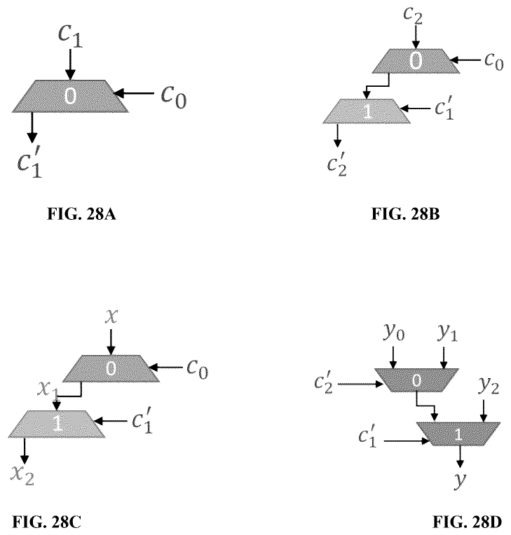

In FIG. 27A suppose c₀, c₁ and c₂ are all defined in B₀. Then Fluid will conditionally generate cf for B₀→B₁ (FIG. 28A) and c₂ for B₀→B₂ (FIG. 28B) as well as the new delivery circuit for B₀→B₂ (FIG. 28C) and the collection circuit for B₅ (FIG. 28D).

### 2.3.5 Handling Non-Canonical CFGs

Multi-Path problem. The case where there are multiple merged paths for src→dst is handled.

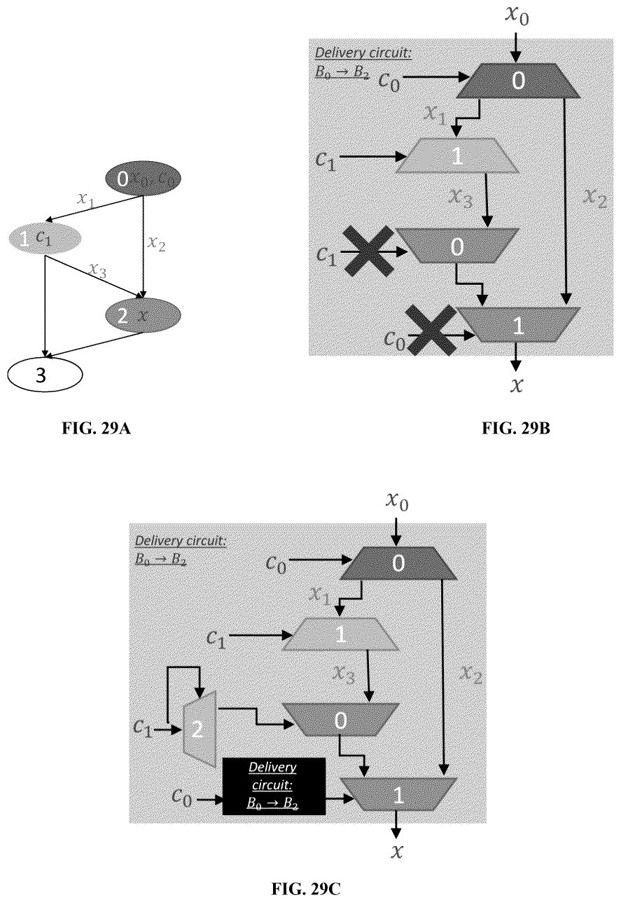

FIG. 29A shows a CFG with four basic blocks, and c₀ and c₁ are the condition variables for B₀ and B₁ respectively. x₀ is defined in B₀ and used in B₂, so it needs a delivery circuit.

FIG. 29B shows the delivery circuit for B₀→B₂. SPLIT₀ (in B₀) would be created to conditionally generate x₁ (for B₁) and x₂ (for B₂). SPLIT₁ (in B₁) would also be needed to conditionally generate x₃ (for B₂). B₂ has two incoming tokens: x₂ with collection condition {c₀=1}, and x₃ with collection condition {c₀=0,c₁=1}. Hence a MERGE₀ and MERGE₁ are needed to select them. However, c₀ and c₁ are defined in B₀ and B₁ respectively, so MERGE₀ and MERGE₁ (in B₂) cannot directly use them.

In FIG. 29C an attempt to introduce split₂ to conditionally propagate c₁ to B₂ was made. However, c₀ is defined in B₀ and used in B₂, and it requires the delivery circuit for B₀→B₂—the same circuit that is attempting to be constructed for x! Hence, the standard approach to constructing a dataflow graph fails if there are multiple paths after the merging operation.

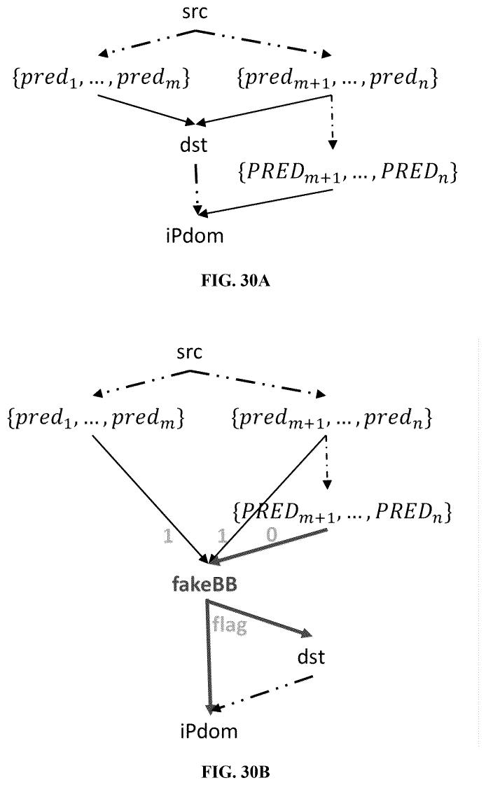

FIG. 30A illustrates the multi-path problem in a CFG. A broken line means there exist paths between two blocks, and the solid line is a direct connection. Assume there are multiple paths for src→dst which cannot be merged into one path. By Theorem 1, dst cannot post-dominate src, so it cannot post-dominate its n direct predecessors between src→dst either. These n predecessors are partitioned into two sets: {pred₁, . . . , predₘ} which are post-dominated by dst, and {predₘ₊₁, . . . , predₙ} which are not post-dominated by dst. Let iPdom be the immediate post-dominator of src. Then there exists paths between {predₘ₊₁, . . . , predₙ} and iPdom without passing through dst. Among these paths, suppose the direct predecessors of iP dom are {PREDₘ₊₁, . . . , PREDₙ}.

FIG. 30B is the proposed solution. The main idea is to modify the CFG and introduce a new basic block that post-dominates src. This new block fakeBB replaces dst, i.e., all of dst's predecessors {pred₁, . . . , predₙ} now point to fakeBB directly. In addition, {PREDₘ₊₁, . . . , PREDₙ} is also modified to point to fakeBB directly. Thus, fakeBB now post-dominates src, and there will be only one merged path for src→fakeBB.

To preserve the correctness, edges are added from fakeBB to iPdom and dst respectively, and a fresh condition variable flag which takes inputs from its direct predecessors {pred₁, . . . , predₙ, PREDₘ₊₁, . . . , PREDₙ} is added. If flag is true, fakeBB jumps to dst; if flag is false, fake BB jumps to iPdom.

{pred₁, . . . , predₙ} have direct connections to dst, so these blocks will propagate token 1 to flag following the same conditions, making fakeBB jump to dst. Similarly, if {predₘ₊₁, . . . , predₙ} jumps to {PREDₘ₊₁, . . . , PREDₙ}, they will propagate 0 to the flag, making fakeBB jump to iPdom. The modified CFG has the same behavior as the original one.

Theorem 4. The above transformation reduces the number of (src,dst) pairs that cause the multi-path problem in a CFG.
Proof. As FIG. 30B shows, a new block fakeBB is added, and three groups of new connections: {PREDₘ₊₁, . . . , PREDₙ}→fakeBB, fakeBB→iPdom and fakeBB→dst. Since fakeBB post-dominates src, there exists only one merged path for src→fakeBB. Furthermore, fakeBB directly connects to iPdom and dst, which does not change the post-dominance relationship between dst and iPdom, so fakeBB does not introduce a new multi-path pair. Therefore, the solution presented herein can eliminate one multi-path pair (src→dst in FIG. 30A).

Irregular Loops. The canonical loop block FIG. 24A requires that each loop block has one loop header block and one loop exit block. Now the case where a loop has more than one exit block and (or) more than one header block is handled.

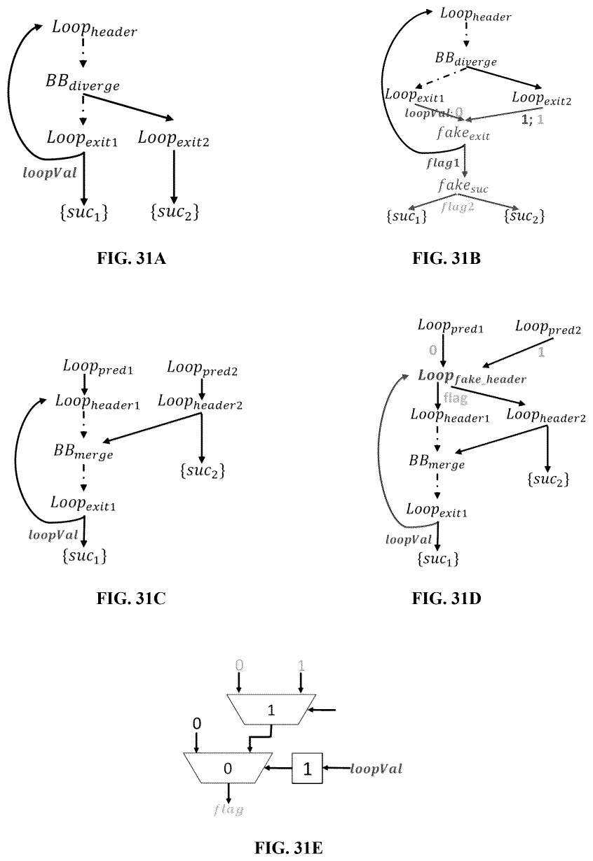

FIG. 31A shows the irregular loop with more than one exit block. When the loop condition variable loopV al is 1, the loop exit block Loopₑₓᵢₜ₁ exits the loop and jumps to its successor set {suc₁}; otherwise the loop continues. However, starting from BB diverge, there is a second exit block Loopₑₓᵢₜ₂.

FIG. 31B shows the solution. Two new blocks fakeₑₓᵢₜ and fake_{suc} are created. The new loop condition variable is flag1. If Loopₑₓᵢₜ₂ is executed, flag1 becomes 1 and the loop exits; otherwise flag 1 equals to loopV al. Therefore, the new CFG has the same behavior of running/exiting the loop as the original.

When the loop exits, fakeₑₓᵢₜ jumps to fake_{suc}. If the loop exits from Loopₑₓᵢₜ₁, flag₂ equals to 0 and {suc₁} will be executed. If the loop exits from Loopₑₓᵢₜ₂, flag₂ equals to 1 and {suc₂} will be executed. Therefore, the new CFG has the same behavior after exiting the loop as the original one.

FIG. 31C shows the irregular loop with more than one header block. The regular loop path is Loop_{pred1}→LOOP_{header1}→BB_{merge}→LOOPₑₓᵢₜ₁→LOOP_{header1}. However, there is a second path that enters the loop: Loop_{pred2}→LOOP_{header2}~>BB_{merge}, which results in a non-canonical loop block.

FIG. 31D shows the solution. A fake block Loop_{fake_header} is created as the actual loop header block, and the previous loop header predecessors, Loop_{pred1} and Loop_{pred2}, both connect to the fake block. Starting from this fake block, the CFG goes to the previous loop headers Loop_{header1} and Loop_{header2} depending on a new condition variable flag. If flag becomes true, the CFG jumps to Loop_{header1}, otherwise it jumps to Loop_{header2}. The remaining blocks are not changed. By doing this, the new loop block has only one “fake” loop header Loop_{fake_header}. Note that Loop_{header2} could connect to other successors {suc₂} other than BB_{merge}, which results in a multi-exit loop. This can be solved using the previous algorithm.

The flag generation is non-trivial though. It takes values from Loop_{pred1} and Loop_{pred2}: when Loop_{pred1} is executed, it propagates token 0 to the flag; when Loop_{pred2} is executed, it propagates token 1 to the flag. However, this will not work. In FIG. 31C although the loop block has two loop headers, the irregular loop header Loop_{header2} gets the chance of being executed only for the first iteration. Assuming that the CFG enter into the loop from this irregular loop header, which results in such execution path Loop_{pred2}→LOOP_{header2}→BB_{merge}→LOOPₑₓᵢₜ₁. Start from Loopₑₓᵢₜ₁, if the loop continues, then it jumps to the regular loop header Loop_{header1} instead of Loop_{header2}. That means, in the solution shown in FIG. 31D Loop_{header2} gets the chance of being executed (i.e., flag=1) only during the first execution of the loop; in the later iteration of the loop, Loop_{header1} should always be executed (i.e., flag=0). FIG. 31E shows the synthesis circuit for flag, which has two MERGEs. The MERGE1 selects from tokens 0 and 1 which come from Loop_{pred1} and Loop_{pred2} respectively, and sends the result to MERGE0, which is controlled by token loopV al. However, loopV al connects to the control port of MERGE0 through a INIT operator with an initial token 1 inside. Therefore, MERGE0 will select the result from MERGE1 during the first iteration of the loop, and always select token 0 (i.e., Loop_{header1} is always executed) if the loop continues (i.e., loopV al=0). When the loop finishes, loopV al=1, which is stored at the INIT operator, so the circuit is restored to the initial state after the execution of the loop.

Summary A canonical CFG—an assumption implicit in previous work-requires that each if statement and loop statement has exactly one exit block. Unfortunately, it is easy to write software programs that violate this requirement. Examples of violations include loop statements that include a break, or a return inside any if or loop statement, both of which are common programming patterns. With the method proposed above, Fluid can process arbitrary goto-free programs.

### 2.4 Alternative Design

Section 2.3 shows the circuit design methodology, which uses the deterministic dataflow elements: MERGE and SPLIT, to encode the software control flow information into the circuit. The major design complexity comes from the control token generation (Sections 2.3.2, 2.3.4, and 2.3.5). There are two alternative designs that simplify the design complexity, and they are studied in this section.

### 2.4.1 MIXER Design

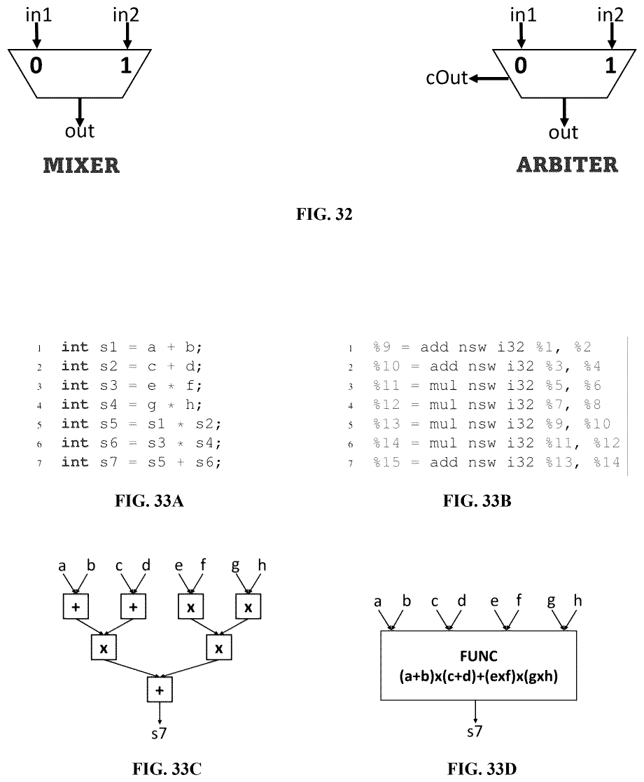

A commonly used non-deterministic dataflow element is the uncontrolled MERGE, which is also called a MIXER. A MIXER shown in FIG. 32 is similar to a MERGE, except it does not have a control token port. A MIXER waits for an input token to arrive on any of its data ports, and propagates the first received input to the output port. If multiple input tokens arrive at the input of a MIXER, the output is non-deterministic; hence, dataflow graphs that use MIXERs often impose a mutual exclusion constraint on input token arrival so as to preserve deterministic execution.

If MIXERS are used in the design, then there is no need to generate the control tokens. For the example, in FIG. 27A token y in B₅ receives multiple definitions (y₀, y₁ and y₂) from its predecessors, and MIXER tree could be synthesized to select the right definition. As a result, the whole if-block (consisting of B₁, B₂, B₃, B₄, B₅) has to be executed in a blocking manner. Consider the case where the CDFG in FIG. 27A is executed twice and generates y₀ and y₂ respectively. The MIXER operator requires mutual exclusiveness on the input ports, so y₂ could not be generated before y₀ is generated. Therefore, all of the branching sub-CDFG are mapped to unpipelined circuits.

### 2.4.2 ARBITER Design

Another non-deterministic dataflow element is ARBITER, shown in FIG. 32 It has two input data ports in1 and in2 and one data output port out. It also has a control output port cOut. The ARBITER would receive input tokens at the input ports and randomly propagate one of them to the output port, and the control output cOut would specify which input data has been chosen. The output of ARBITER is non-deterministic, so dataflow graphs with ARBITERs often impose in-order constraints on input token arrival for deterministic execution.

For the example in FIG. 27A Fluid synthesizes the collection circuit (FIG. 27C) to conditionally generate y from multiple definitions, which requires control tokens c₁ and c₂. The ARBITER could be used to generate the desired control tokens. However, the ARBITERs require in-order execution of the input tokens, so y₀, y₁ and y₂ have to be generated in the same order. To achieve that, the if-block (consisting of B₁, B₂, B₃, B₄, B₅) has to be non-pipelined.

Summary The C programs require deterministic execution in nature. When the HLS engine maps them to hardware, it could reduce the design complexity by using the non-deterministic hardware operators. However, the HLS engine has to synthesize (partially) unpipelined circuits to get the deterministic results.

### 2.5 Dataflow Graph Optimizations

Fluid converts the optimized LLVM IR into STF form, which is essentially a dataflow graph. In this section, the focus is on optimizing the dataflow graph.

### 2.5.1 Operator Clustering

LLVM encodes expressions into three-address IR instructions, and Fluid maps each of them into a dataflow operator, which is an independent pipelined process. For complex expressions, Fluid generates many dataflow operators and misses opportunities for logic optimizations across expressions. Therefore, it is desirable to group them together.

FIG. 33A shows an example code for a chain of arithmetic operations, and FIG. 33B shows the corresponding IR instructions generated by LLVM. For example, LLVM maps

$${}_{1} int s 1 = a + b ;$$

into the IR instruction

$${}_{1} \%9 = add nsw i 32 \%1 , \%2 .$$

The instruction specifies the add operation as well as the data types i32 for both operands and the result. The values (for operands and the result) are stored in the virtual registers such as % 1, % 2, % 9. Fluid will synthesize a FUNC operator to perform the add computation, and the input (output) channels of the operator carry the operands (result) of the operator.

FIG. 33C shows the vanilla dataflow graph Fluid generated directly from the LLVM IR (FIG. 33B). It contains four multipliers and three adders, as is specified by the example code (FIG. 33A). However, these operations are purely combinational logic, and Fluid groups these operations together and applies logic optimizations to generate a faster and smaller circuit (FIG. 33D).

However, operations could not be naively clustered together by tracking the def-uses of each variable in the vanilla dataflow graph. The CFG of the source program divides the segments of codes into different control zones, and similarly the control nodes (i.e., MERGE and SPLIT) divide the whole graph into distinct control regions as well, and operator clustering is only applicable to nodes within the same control region.

To identify the clustering opportunities, colors were assigned to each graph edge based on the condition it is activated. The in/out edges to a FUNC or a COPY node have the same color. The guard and input data edges of a SPLIT, or the guard and output edges of a MERGE, are also assigned the same color. The BUF and INIT nodes would generate a new color. The SOURCE operator only has an output edge, so it generates the initial color. The SINK operator only has an input edge, so it does not change any color, and can be clustered together with its predecessor. After coloring the dataflow graph as specified, the FUNC nodes whose output edges have the same color can now be safely clustered.

### 2.5.2 MERGE and SPLIT Tree Flattening

In Section 2.3, Fluid synthesizes MERGES and SPLITS for each unique condition variable in the collection and delivery conditions, potentially generating a tree of 2-way MERGES and SPLITS. Fluid further flattens them into the N-way MERGE and SPLIT, which reduce the delay, area and energy consumption.

To perform this transformation, a new control token needed to be created using the control tokens for the 2-way MERGES or SPLITS. For a SPLIT tree, the top SPLIT was marked as “parent” node, and all the SPLITS below as “child” node. The control tokens to the child node should be generated by a SPLIT whose input has the same color as the parent node's control token, or by a function of such SPLITS.

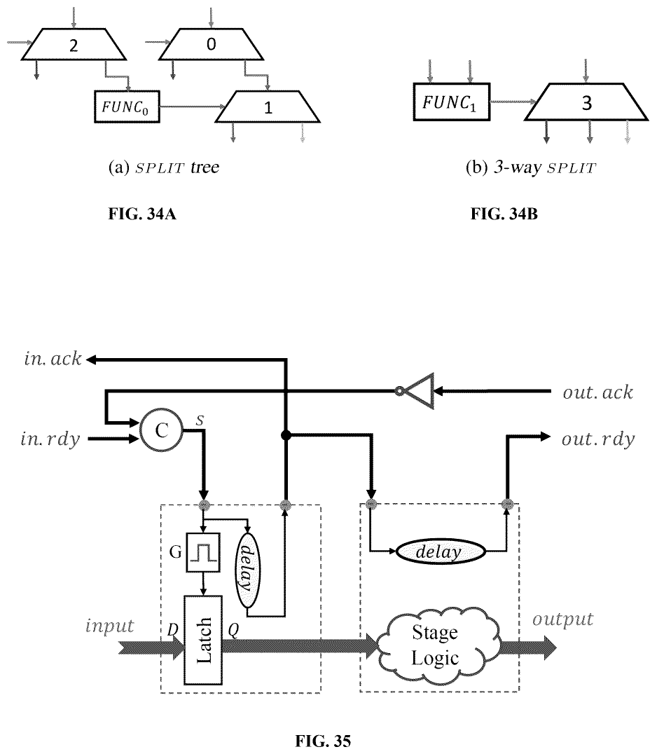

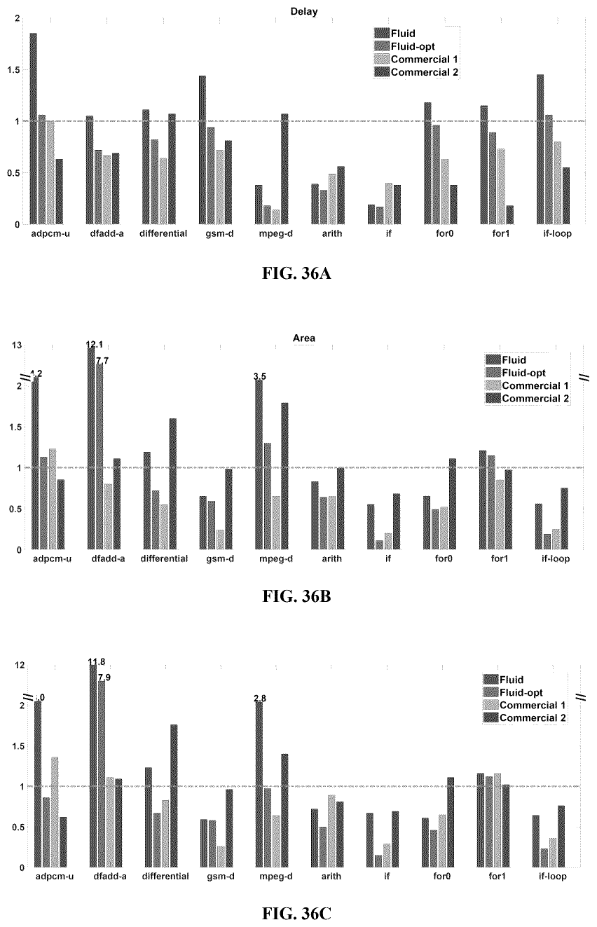

FIG. 34A shows a SPLIT tree which consists of SPLIT 0 (parent node) and SPLIT1 (child node). For SPLIT 0, its input data and control edges are colored grey, its left output edge (i.e., LOut0) is colored red, and its right output edge (i.e., ROut0) is colored blue. Since ROut0 is also the input data edge to SPLIT1, its control edge is colored blue as well. Lastly, the left (right) output edge of SPLIT1 is colored as green (orange).

Let's focus on CTRL1 (the control edge of SPLIT1), which has the same color (i.e., within the same control zone) with ROut0. Therefore, CTRL1 either directly comes from ROut0, or comes from another SPLIT2 whose input data and control edges are also colored gray (there could be FUNC blocks on the way). FIG. 34A shows the latter case. As shown in FIG. 34B, Fluid flattens SPLIT0 and SPLIT1 into a 3-way SPLIT3, and the input to SPLIT3 is the same as the input to SPLIT0. Fluid synthesizes a FUNC1 block to calculate the new control token, whose inputs are the control token of SPLIT0 and the input token of SPLIT2. If the outputs of SPLIT2 are not used elsewhere, Fluid deletes SPLIT2.

### 2.6 Evaluation

### 2.6.1 Control Circuit Synthesis

Each dataflow graph component is translated into a unique pipeline stage, and the data transfers between pipelined stages use the bundled data protocol. The control for each pipelined stage uses micro-pipelines.

FIG. 35 shows a standard bundled data circuit template that is used in the evaluations. The control path is the upper part in bold lines, and the data path is within the dashed boxes. The stage logic implements the function in the dataflow node, and the control circuit implements the four-phase handshake using a Muller C-element (C). When the input token is ready (in.rdy signal is high), and the successor stage is empty (out.ack is low), C's output signal s becomes high, which triggers data capture using a pulse generator G and latch, and then the execution of the stage logic. When the output token is ready, the out.rdy signal is set to high. After the next stage captures this data, it will set the acknowledged signal out.ack to high, allowing the current stage to reset. Delay lines (15% slower than the worst-case delay of the stage logic) are added to ensure successful data capturing and processing.

### 2.6.2 Simulation Methodology

In order to simulate and measure the performance of synthesized asynchronous circuits, a discrete-event simulator that can simulate the execution of the bundled data circuits in FIG. 35 was built. Each pipelined process fetches data from the predecessors and sends out results to its successors, and the simulator simulates the 4-phase handshake for process communication. Performance numbers for different circuit components are extracted using commercial tools, and used to annotate the discrete event simulator. Specifically, HSPICE was used to simulate the control circuit in a 28 nm process technology. For the stage datapath logic (combinational), commercial logic synthesis tools and a commercial 28 nm standard cell library were used to determine performance/power/area. The delay of each stage is the sum of the delay of the control circuit and the stage logic (as shown in FIG. 35). Synchronous results were obtained using the same cell library and same commercial logic synthesis tool.

### 2.6.3 Experimental Setup

Benchmark. The following microbenchmarks were synthesized:
1. arith, which performs the same arithmetic computation as the example code in FIGS.

$$33 A - D i . e . , y = ( {x}_{0} + {x}_{1} ) \times ( {x}_{2} + {x}_{3} ) + ( {x}_{4} \times {x}_{5} ) \times ( {x}_{6} \times {x}_{7} ) .$$

2. if, which is the same if statement as the example code in FIG. 21A. The true branch does the addition and the false branch does division. The true branch will be triggered during runtime.
3. for0, which has a single loop which sums the integers from 0 to 9.
4. for1, which has two-layer nested loops. In the outer layer, the integer counter iterates over 0 to 9; in the inner layer, the integer counter iterates over 0 to 1, and increases the sum by 1 for every iteration.
5. if-loop which has an if statement: the true branch has a one-layer loop (count from 0 to 9) and the false branch which does the division. The true branch will be triggered during runtime.
   Five kernel functions were also extracted from five applications which are mostly taken from an HLS benchmark suite or used in synchronous ASIC synthesis benchmarking:
1. differential, a differential equation solver;
2. adpcm-u, the uppol2 function from adpcm;
3. dfadd-a. The add function from dfadd;
4. gsm-d. The gsm_div function from gsm;
5. mpeg-d. The decode function from mpeg.

Comparison. The presently described tool is compared with LegUp v4.0 which is a commonly used academic HLS tool, and two commercial HLS tools Commercial 1 and Commercial 2. Furthermore, Fluid (vanilla version of Fluid) and Fluid-opt (Fluid with dataflow optimizations) are included.

Metrics. The following performance metrics are used: Delay (ps), Area (μm₂), Energy (pJ), LeakPower (nW) and Throughput (MHz). In order to get the throughput, each benchmark application is run 20 times and the total delay D (ps) is recorded. The throughput is calculated as

$$\frac{20 \times {10}^{6}}{D} ( MH 𝓏 ) .$$

Fluid will directly extract the performance numbers from the annotated circuit simulator. LegUp, Commercial 1 and Commercial 2 all generate RTL designs from C programs. Commercial tools are used to do logic synthesis and optimizations, and measure the delay, area, dynamic power and leak power of the synthesized circuits. In order to measure their energy, the circuit's total power (dynamic power+leak power) multiplying its delay is used.

Each benchmark is run twenty times (the input data are provided by each benchmark, and there are dozens of them to cover different cases) and averages are used across the runs to report benchmark statistics. The same methodology is used to collect results for both Fluid and the other HLS tools.

### 2.6.4 Experimental Results

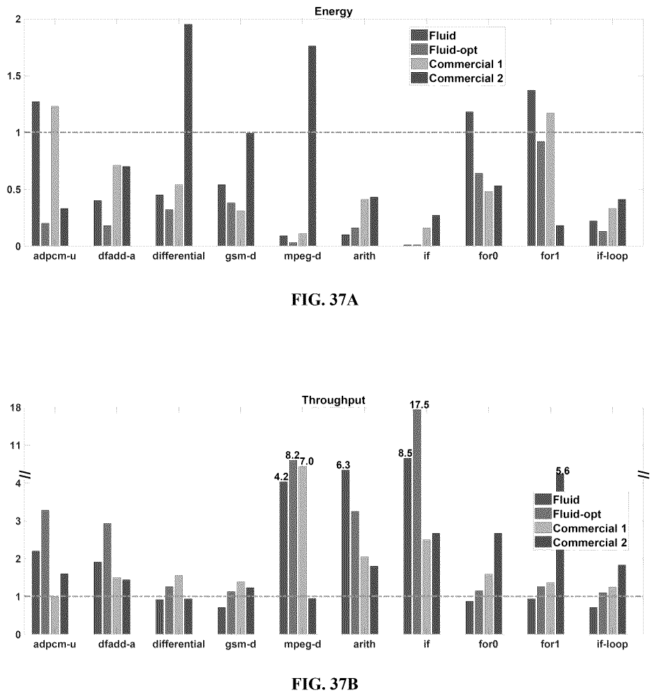

Table 3.1 shows the performance of the system described herein, and Table 3.2 shows other tools. FIGS. 36A-37B show the performance breakdown for all of the tools.

Each table has three sections: the first shows the performance of HLS benchmarks, and the second shows the performance of microbenchmarks. To summarize across benchmarks, the geometric mean of the normalized performance compared to LegUp is used; Ratio1 corresponds to the HLS benchmarks, and Ratio2 corresponds to microbenchmarks.

TABLE 3.1
Fluid and Fluid-opt Performance

| | Fluid | | | | | Fluid-opt | | | | |
|---|---|---|---|---|---|---|---|---|---|---|
| Benchmark | Delay | Area | Energy | Leak. | Throu. | Delay | Area | Energy | Leak. | Throu. |
| adpcm-u | 11104 | 33814 | 84 | 10331 | 367 | 4588 | 7381 | 10 | 2424 | 560 |
| dfadd-a | 9445 | 132021 | 31 | 35081 | 212 | 7415 | 64258 | 8 | 18905 | 278 |
| differential | 226516 | 19051 | 1545 | 6217 | 4 | 165814 | 11180 | 1007 | 3365 | 6 |
| gsm-d | 41378 | 6301 | 95 | 1721 | 25 | 26861 | 5274 | 51 | 1607 | 39 |
| mpeng-d | 15844 | 22233 | 24 | 7147 | 99 | 7523 | 7285 | 5 | 2231 | 193 |
| arith | 4378 | 10872 | 20 | 3634 | 563 | 3548 | 9268 | 29 | 3058 | 289 |
| if | 1858 | 8506 | 2 | 2926 | 854 | 1566 | 1650 | 1 | 639 | 1754 |
| for0 | 19680 | 2596 | 55 | 755 | 52 | 13628 | 2080 | 18 | 714 | 80 |
| for1 | 40079 | 4927 | 175 | 1410 | 26 | 30843 | 4356 | 61 | 1341 | 36 |
| if-loop | 19946 | 10428 | 56 | 3469 | 52 | 14458 | 3410 | 18 | 1252 | 81 |
| Ratio1 | 1.03 | 2.68 | 0.41 | 2.35 | 1.63 | 0.61 | 1.19 | 0.12 | 1.08 | 2.50 |
| Ratio2 | 0.68 | 0.73 | 0.21 | 0.74 | 1.99 | 0.52 | 0.38 | 0.11 | 0.42 | 2.54 |

TABLE 3.2
Performance of LegUp 4.0 and two commercial HLS tools

| | Commercial 1 | | | | | Commercial 2 | | |
|---|---|---|---|---|---|---|---|---|
| Benchmark | Delay | Area | Energy | Leak. | Throu. | Delay | Area | Energy |
| adpcm-u | 6000 | 9846 | 81 | 4616 | 167 | 3750 | 6825 | 22 |
| dfadd-a | 6000 | 8780 | 55 | 3282 | 167 | 6250 | 12154 | 54 |
| differential | 130000 | 8771 | 1861 | 4208 | 8 | 217778 | 25491 | 6732 |
| gsm-d | 20667 | 2349 | 55 | 776 | 48 | 23333 | 9502 | 175 |
| mpeng-d | 6000 | 4096 | 28 | 1651 | 167 | 45000 | 11305 | 470 |
| arith | 5500 | 8584 | 83 | 4512 | 182 | 6250 | 13026 | 88 |
| if | 4000 | 3128 | 25 | 1273 | 250 | 3750 | 10482 | 41 |
| for0 | 10500 | 2082 | 22 | 800 | 95 | 6250 | 4396 | 25 |
| for1 | 25600 | 3447 | 149 | 1421 | 39 | 6250 | 3949 | 23 |
| if-loop | 11000 | 4699 | 86 | 1960 | 91 | 7500 | 14034 | 105 |
| Ratio1 | 0.53 | 0.61 | 0.43 | 0.73 | 1.87 | 0.83 | 1.22 | 0.95 |
| Ratio2 | 0.59 | 0.43 | 0.42 | 0.59 | 1.69 | 0.38 | 0.89 | 0.34 |

| | Commercial 2 | | Legup | | | | |
|---|---|---|---|---|---|---|---|
| Benchmark | Leak. | Throu. | Delay | Area | Energy | Leak. | Throu. |
| adpcm-u | 2123 | 267 | 6000 | 8013 | 66 | 3405 | 167 |
| dfadd-a | 3241 | 160 | 9000 | 10941 | 77 | 2964 | 111 |
| differential | 8907 | 5 | 203333 | 15948 | 3451 | 5061 | 5 |
| gsm-d | 2813 | 43 | 28750 | 9682 | 176 | 2934 | 35 |
| mpeng-d | 3587 | 22 | 42222 | 6327 | 267 | 2565 | 24 |
| arith | 4106 | 160 | 11250 | 13156 | 204 | 5074 | 89 |
| if | 3006 | 267 | 10000 | 15342 | 153 | 4342 | 100 |
| for0 | 1376 | 160 | 16667 | 3974 | 47 | 1237 | 60 |
| for1 | 1245 | 160 | 35000 | 4065 | 127 | 1220 | 29 |
| if-loop | 4119 | 133 | 13750 | 18772 | 257 | 5432 | 73 |
| Ratio1 | 1.10 | 1.20 | 1 | 1 | 1 | 1 | 1 |
| Ratio2 | 0.86 | 2.65 | 1 | 1 | 1 | 1 | 1 |

Delay. FIG. 36A shows the delay comparison. Fluid has a longer delay for two reasons: 1) it fails to do logic optimizations for operator clusters; 2) it synthesizes MERGEs and SPLIT s which contribute to the extra delay. Fluid-opt can avoid the extra delay from reason 1. However, neither of them performs well for for0, for1 or if-loop. These three benchmarks are basically simple loops, so Fluid and Fluid-opt spend quite a lot of time on the MERGE trees and the SPLIT trees.

For if benchmark, Fluid and Fluid-opt perform well because they generate asynchronous circuits whose actual delay depends on the activated processes during runtime (i.e., the addition). The other tools, however, are limited by the worst-case scenario (e.g. division) when generating the global state machine for the circuits.

Fluid-opt reduces delay by 1.64× and 1.92× for HLS benchmarks and microbenchmarks respectively.

Area and Leakage. Compared with synchronous circuits, the asynchronous circuits need to pay extra cost for the control circuitry (Section 2.6.1) as well as the control elements MERGES and SPLITS (Section 2.3). On the other hand, the asynchronous circuit does not require a global state machine to control the circuit execution, which saves area. Fluid-opt applies operator clustering algorithm, which could leverage the logic optimizations opportunities for combinational computations, which could further reduce the area. Note that Legup, Commercial 1 and Commercial 2 all use commercial tools to do logic optimizations on their generated circuits, so the operator clustering is also applied on their outputs by the commercial tools.

FIG. 36B shows the normalized area performance. Note that the y-axis is truncated at y=2 position for illustration purposes. Fluid and Fluid-opt performs badly in dfadd-a, because this benchmark has many-layer nested if statements and loop statements, and the system described herein generates huge MERGE trees and SPLIT trees to collect and deliver data tokens. But for other benchmarks, the system described herein can achieve similar or even better performance in terms of area.

It is worth noting that Fluid-opt improves a lot in area compared with Fluid. It is because Fluid-opt could cluster multiple operators into one and do logic optimizations to it as well as flatten the MERGE and SPLIT trees, which reduces area by a large portion.

Fluid-opt increases HLS benchmark area by 1.19χ, while reducing it by 2.63× for microbenchmarks.

Leakage power results are qualitatively similar to those for area.

Energy. Compared with synchronous design, asynchronous circuits only activate the processes that receive the input data, which could save energy. On the other hand, asynchronous circuits need to pay extra cost for the control circuits for each process to communicate with other processes.

FIG. 37A shows the normalized energy performance. Fluid and Fluid-opt achieve better energy performance in most benchmarks. However, in for0 and for1, Fluid have higher energy consumption, since it needs to synthesize multiple MERGE and SPLIT trees for the data tokens. Fluid-opt could further improve energy performance compared with Fluidby doing logic optimizations for the combinational operator clusters.

Table 3.1 shows that Fluid-opt reduces energy by 8.33× and 9.09× for HLS benchmarks and microbenchmarks compared to LegUp.

Throughput. Fluid synthesizes highly pipelined circuits, which could effectively increase the circuit throughput. As shown in FIG. 37B, Fluid and Fluid-opt has higher throughput than other tools for most of the benchmarks.

Note that the operator clustering optimization by Fluid-opt has two-sided effects on throughput: on one hand, it could reduce the latency of operator clusters (thus the whole circuit), which could increase the throughput; on the other hand, creating a large combinational operator out of multiple smaller combinational operators would reduce the pipeline stages and thus reduce the throughput. Fluid has higher throughput than Fluid-opt for arith benchmark, but it has lower throughputs than Fluid-opt in other benchmarks, so the operator clustering optimization in general is beneficial for throughput improvement.

Fluid and Fluid-opt do not perform well for loop benchmarks (for0 and for1). This is because these two benchmarks have quite simple loop bodies, and their throughputs are limited by the loop dependencies. This work does not optimize for loops specifically, so Fluid and Fluid-opt have mediocre performance for benchmarks whose throughputs are mainly bounded by loop dependencies.

Table 3.1 shows that Fluid-opt has higher throughput than Fluid for most benchmarks. Fluid-opt increases the throughput by 2.5× for HLS benchmarks, and 2.54× for microbenchmarks compared to LegUp.

Comparison with CPU. The performance comparison between Fluid-opt, which generates the ASIC implementations for the benchmarks, and the CPU implementations is studied by directly running the benchmarks on commodity servers. GCC 10.2.0 is used as the C-compiler, and the optimization level is turned on —O2.

TABLE 3.3
Fluid-opt vs CPU implementation

| Benchmark | CPU runtime (ps) | Fluid runtime (ps) | Speedup (X) |
|---|---|---|---|
| adpcm-uppol2 | 166481 | 4588 | 36.29 |
| dfadd | 256971 | 7415 | 34.66 |
| differential | 256471 | 165814 | 1.55 |
| gsm-div | 288467 | 26861 | 10.74 |
| mpeg-decode | 167981 | 7523 | 22.33 |
| arith | 146983 | 3548 | 41.43 |
| if | 161482 | 1566 | 103.12 |
| for0 | 158482 | 13628 | 11.63 |
| for1 | 165981 | 30843 | 5.38 |
| if-loop | 174480 | 14458 | 12.07 |

Table 3.3 shows the runtime comparison for Fluid-opt and the CPU implementation. The ASIC implementation could achieve 30×-100× speedup for most benchmarks. However, if the benchmarks mainly have loops (gsm-div, differential, for0, for1, if-loop), the ASIC implementations have limited speedup. For differential benchmark, it is essentially a loop whose body consists of multiple multiplications. Fluid could not pipeline the loop well due to the loop dependency, and it also generated expensive (in terms of delay) circuits for the multiplication.

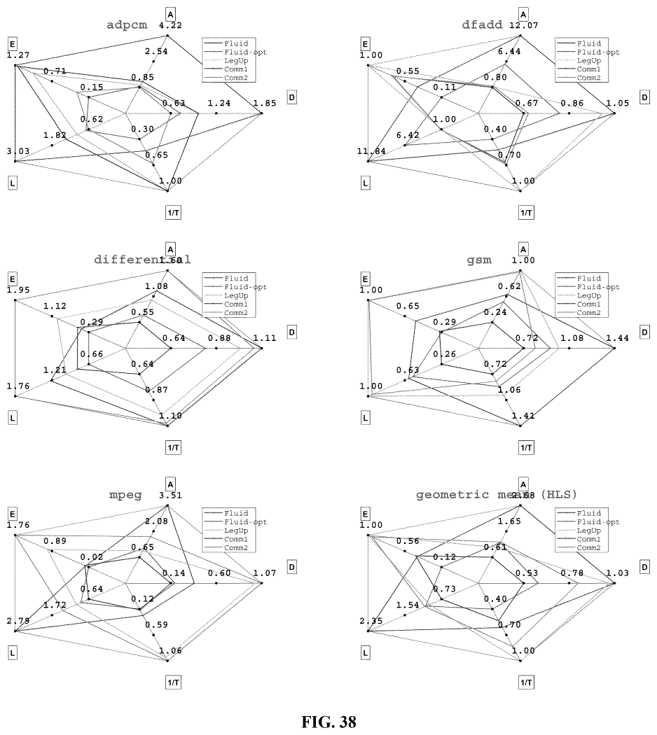

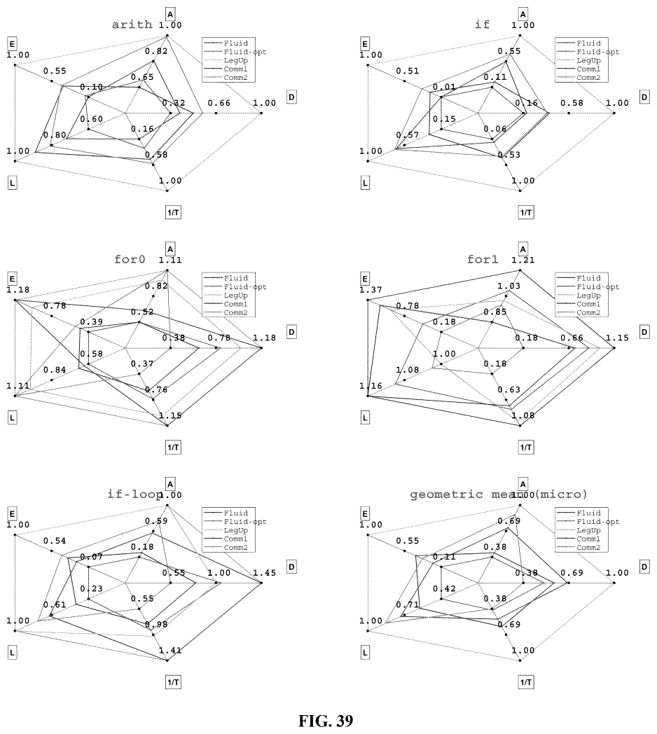

Overall performance. No HLS tool is consistently the best in all metrics across all benchmarks, and the key is to achieve good trade-off among the metrics. Therefore, FIG. 38 shows per-benchmark spider plots of normalized performance as well as the geometric mean of the normalized performance of HLS benchmarks, and FIG. 39 shows those for the micro benchmarks. The inverse of the normalized throughput is plotted, so for all metrics lower is better. Fluid-opt achieved a good balance among the five metrics for most of the benchmarks. Note that Fluid by itself rarely compares favorably against commercial HLS tools, so the dataflow graph optimizations are an essential ingredient of the overall flow.

### 2.7 Summary

A new solution to dataflow circuit generation that can handle real applications with complex control structures is proposed. Also included is dataflow optimization prior to generating the final asynchronous circuit, including optimizations that can handle conditional components. This work is compared against three HLS tools, and it is shown that this work achieves improvements in terms of energy and throughput.

While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. A method of forming a fully-pipelined dataflow circuit, the method comprising:
mapping a program into the dataflow circuit through dataflow high-level synthesis (HLS), the dataflow HLS including:
a compilation stage comprising synthesizing functions into separate hardware modules; and
a linking stage comprising generating logic to combine the hardware modules into a whole program dataflow graph; and
generating the dataflow circuit;
wherein at least one link in the dataflow circuit is slack elastic.

2. The method of claim 1, wherein the synthesizing of the functions into the separate hardware modules includes mapping of each function that does not involve function calls into the separate hardware modules.

3. The method of claim 2, wherein the functions are mapped into independent circuits.

4. The method of claim 3, wherein the independent circuits are independent asynchronous dataflow circuits.

5. The method of claim 1, wherein the compilation stage includes synthesizing dangling dataflow connections across functions.

6. The method of claim 5, wherein the linking stage includes constructing a pipelined linking circuit, the pipelined linking circuit resolving the dangling dataflow connections.

7. The method of claim 6, wherein constructing the pipelined linking circuit includes generating a pipelined resource sharing system.

8. The method of claim 6, wherein constructing the pipelined linking circuit includes forming an adaptive control token network (ACTN).

9. The method of claim 8, wherein forming the ACTN includes generating at least one use-resource token.

10. The method of claim 9, wherein each use-resource token determines how many times a function is called at run-time by a program fragment.

11. The method of claim 10, wherein a different use-resource token is generated for each different invocations of the program fragment.

12. The method of claim 10, wherein:
the program includes at least one sequential composition;
the at least one sequential composition has at least two sub-programs composed in a sequential fashion; and
each of the at least two sub-programs has at least one possible invocation of the same function.

13. The method of claim 12, further comprising:
introducing a MERGE block, the MERGE block routing an argument to the function;
introducing a SPLIT block, the SPLIT block routing a return value from the function;
computing the use-resource token for the sequential composition from the at least two sub-programs; and
generating a control token, the control token routing data tokens through the MERGE and SPLIT blocks.

14. The method of claim 13, further comprising inserting a first in, first out (FIFO) buffer at the SPLIT block.

15. The method of claim 10, wherein the program includes at least one conditional composition, the at least one conditional composition calling one or more of the functions in a conditional fashion.

16. The method of claim 15, further comprising:
introducing a MERGE block, the MERGE block routing a conditional argument to the function;
introducing a SPLIT block, the SPLIT block routing a return value according to the conditional argument from the function;
computing a conditional use-resource sequence for each conditional branch;
computing the use-resource token for the conditional composition from the conditional use-resource sequences; and
generating a control token, the control token routing data tokens through the MERGE and SPLIT blocks.

17. The method of claim 16, further comprising inserting a first in, first out (FIFO) buffer at the SPLIT block.

18. The method of claim 10, wherein the program includes at least one iterative composition, the at least one iterative composition calling one or more loops of the function.

19. The method of claim 18, further comprising computing the use-resource token for the iterative composition, the use-resource token being run-length encoded with the number of loops in the iterative composition.

20. The method of claim 9, further comprising:
introducing a proxy function for indirect function calls; and
generating a use-resource token network including direct function call use-resource tokens and indirect function call use-resource tokens.

21. The method of claim 20, further comprising generating incremental linking to route data from the proxy function to the function.

22. The method of claim 21, further comprising generating one or more control tokens for the incremental linking.

23. The method of claim 1, further comprising treating both memory blocks and function blocks as shared resource blocks.

24. The method of claim 23, further comprising generating one or more function pointer arguments.

25. The method of claim 1, further comprising clustering FUNC operators within a basic block into a monolithic FUNC operator.

26. The method of claim 1, further comprising MERGE and SPLIT flattening.

27. The method of claim 1, further comprising fusing at least one SPLIT and MERGE pair.

28. The method of claim 1, further comprising clustering FUNC modules across basic block boundaries.
